(19) United States
(12) Patent Application Publication
(10) Pub. No.: US 2010/0275971 A1
(43) Pub. Date: Nov. 4, 2010

(54) Scalable Dense PV Solar Receiver for High Concentration

(76) Inventor: Arthur R Zingher, Mountain View, CA (US)

Correspondence Address: WILLIAM J. KOLEGRAFF, 3119 TURNBERRY WAY, JAMUL, CA, 91935, US

(21) Appl. No.: 12/419,265

(22) Filed: Apr. 6, 2009

Related U.S. Application Data
(60) Provisional application No. 61/123,103, filed on Apr. 4, 2008.

(51) Int. Cl. H01L 31/052; H05K 1/00; H05K 1/05

(52) U.S. Cl. 136/246; 174/250; 174/256; 174/258; 174/252

(57) ABSTRACT

A solar receiver and system is provided that generates electrical power generation from very highly concentrated sunlight. The system has advantages in: cooling and packaging for electrical power devices; electrical circuit impedance; and low frequency and high frequency electrical properties.

In one example, a Photo-voltaic Many Cell Module (“PvMcm”) includes a large substrate with many photo-voltaic (“PV”) cells mounted in a dense array. This substrate has a core of solid molybdenum, insulated on both faces with aluminum nitride. Atop this is one layer of molybdenum printed wire. This electrically connects the PV cells. Atop this is another dielectric layer. This substrate provides excellent thermal resistivity. This receiver also includes a Switch Many Chip Module (“SwMcm”) to convert DC to AC electrical power. This includes a second substrate that carries power switches mounted tightly on one surface. This substrate includes a metal core, ceramic insulation and several layers of printed wiring.

A cold-plate provides water cooling for both the PvMcm and SwMcm. This can amply cool 100 W/cm̂2 heat flux throughout the PvMcm. Also this improves inverter reliability. There may be a redundant protection against overheating. Along the optical path for sunlight, there is a shutter that is interlocked with cooling. This shutter can allow or else rapidly prevent highly concentrated sunlight on the PvMcm.

### RELATED APPLICATIONS

This application claims priority to U.S. provisional patent application No. 61/123,103 filed Apr. 4, 2008 and entitled, “Solar photovoltaic dense many-chip module & system”, which is incorporated herein in its entirety.

### FIELD OF INVENTION

The field of the present invention is devices and processes for solar power generation. More particularly, the present invention teaches a system to harvest concentrated sunlight using PV cells to generate electrical power and to convert (“invert”) this to AC power. Therefore this invention provides suitable electronic packaging, electrical power circuits, and cooling.

### PRIOR ART

### Known Solar Structures

U.S. Pat. No. 6,531,653 and also US patent application 2003/0047208; both by Glen & Sherif; both filed 2001 Sep. 11; both assigned to Boeing; and both titled “Low cost high solar flux PV concentrator receiver”. The PV cell connects through a wrap-around electrical conductor, so positive and negative electrodes are both on the back surface of the PV cell. The substrate includes two metallic layers with a dielectric between them.

U.S. Pat. No. 6,686,533; by Baum, Halfon & Steinman; assigned to Israel Aircraft Industries; filed 2002 Jan. 29; and titled “System & method for converting solar energy into electricity”.

US patent application 2005/0072457; by Glen; not assigned; files 2003 Oct. 2; and titled “Solar Cell Structure with integrated by-pass diode”. Each PV cell is mounted on a small carrier, which also provides an integrated by-pass diode plus positive and negative terminals both on the same surface.

U.S. Pat. No. 7,235,736; by Bueller & Beck; assigned to Solyndera Inc; filed 2006 Mar. 18; and titled “Monolithic integration of cylindrical solar cells”

US patent application 2008/0047599; by Bueller & Beck; assigned to Solyndera Inc; filed 2006 May 3; and titled “Monolithic integration of cylindrical solar cells”

### Known Cooling Structures

U.S. Pat. No. 4,361,717; by Gilmore et al; assigned to General Electric Co; filed 1980 Dec. 5; and titled “Fluid cooled solar powered PV cell”

U.S. Pat. No. 5,265,670 by Zingher and Gruber; assigned to IBM; and titled “Convection Transfer System”. This describes a Cold Hat for high density cooling using impingement of many small jets on pumped water.

U.S. Pat. No. 5,310,440 by Zingher and Gruber; assigned to IBM; and titled “Convection Transfer System”. This describes a Cold Hat for high density cooling by pumped water flowing small distances across a smooth surface.

U.S. Pat. No. 5,388,635; by Gruber and Zingher; assigned to IBM; and titled “Compliant Fluidic Coolant Hat”. This describes a Cold Hat for high density cooling using fine fins and grooves and pumped water.

U.S. Pat. No. 6,745,830 by Khanh Dinh; assigned to IBM; and titled “Heat Pipe Loop with Pump Assistance”. This describes a thermo-siphon heat pipe with an explicit pump to assist flow of liquid

U.S. Pat. No. 7,076,965; by John Lasich; not assigned; filed PCT on 2002 Oct. 10; and titled “Cooling circuit for receiver of solar radiation” This teaches cooling for a PV solar power. A preferred embodiment includes a module with a dense array of 64 PV cells. Concentrated solar power generates electrical power, and also produces heat. This conducts out the back of each PV cell, through a metalized ceramic substrate, and through a copper plate with fins and grooves. Through these grooves, water flows and convects away heat. In a preferred embodiment, a solar receiver includes 8*8 discrete modules in a dense array. Each module includes a pair of discrete electrical connectors for electrical output power. A large parabolic dish concentrates sunlight onto all modules and PV cells in this receiver. In total, this receiver can harvest about 20 kW of electrical power, and can remove corresponding by-product heat.

U.S. Pat. No. 6,990,816 by J. Zuo & D. Sarraf; assigned Adv. Cooling Tech.; filed 2004 Dec. 22; and titled “Hybrid capillary cooling apparatus”. This teaches a loop heat pipe with a reservoir for condensed coolant, plus a pump from reservoir to evaporator, plus a return tube from evaporator to reservoir. Liquid coolant is pumped to the evaporator, and any excess liquid returns to the reservoir.

US patent 2007/0089775; by John Lasich; not assigned; filed PCT on 2004 Aug. 30; and titled “Extracting heat from an object”. A preferred embodiment is similar to U.S. Pat. No. 7,076,965, except for the following. Heat conducts out the back of each PV cell, through an AlN substrate, through copper beads which are sintered together in a three-dimensional labyrinth. Water flows in a labyrinth of flow paths, and convects away heat.

US patent application 2007/0083450; by Benoit et al; assigned to United Tech Corp; filed 2006 Oct. 4; and titled “Thermal management of concentrator PV cells”

US patent application 2007/021519; by Jiang et al; assigned to United Tech Corp; filed 2006 Mar. 16; and titled “Solar cell system with thermal management”US patent application 2007/0028960; by Royne & Dey; filed 2005 Aug. 3; and titled “Active Cooling Device”. This teaches impingement liquid cooling. Does NOT provide additional features needed for cooling of large-scale substrate.

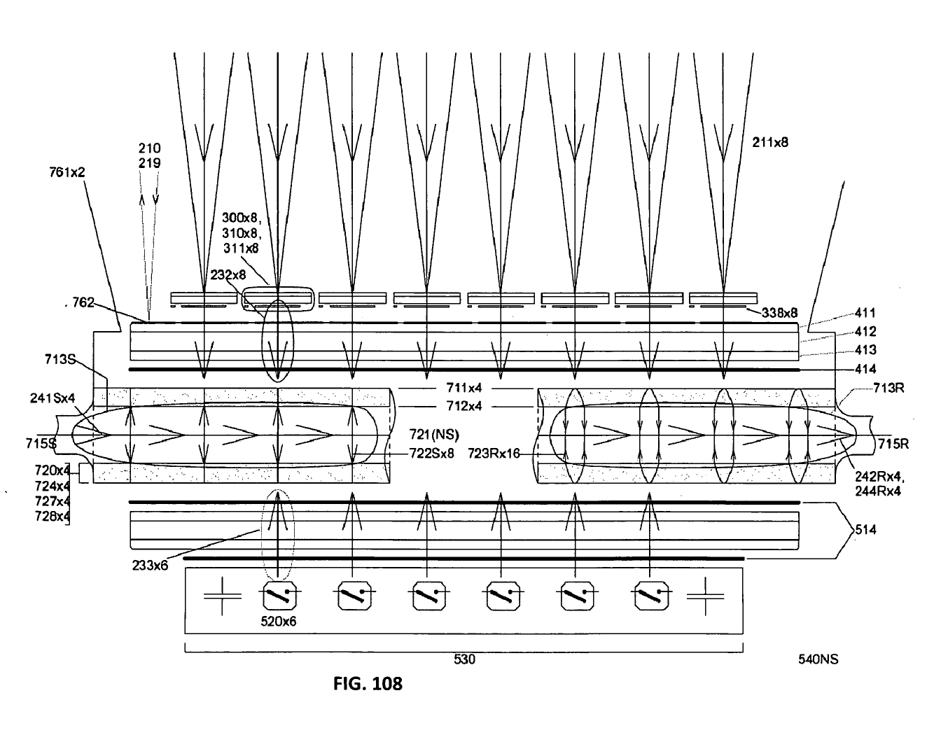

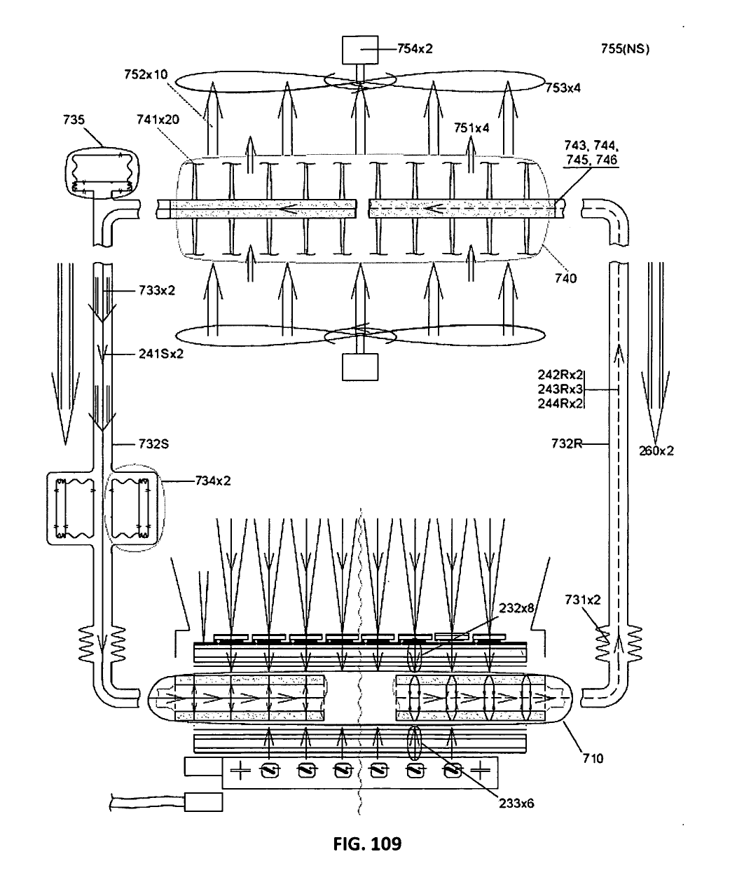

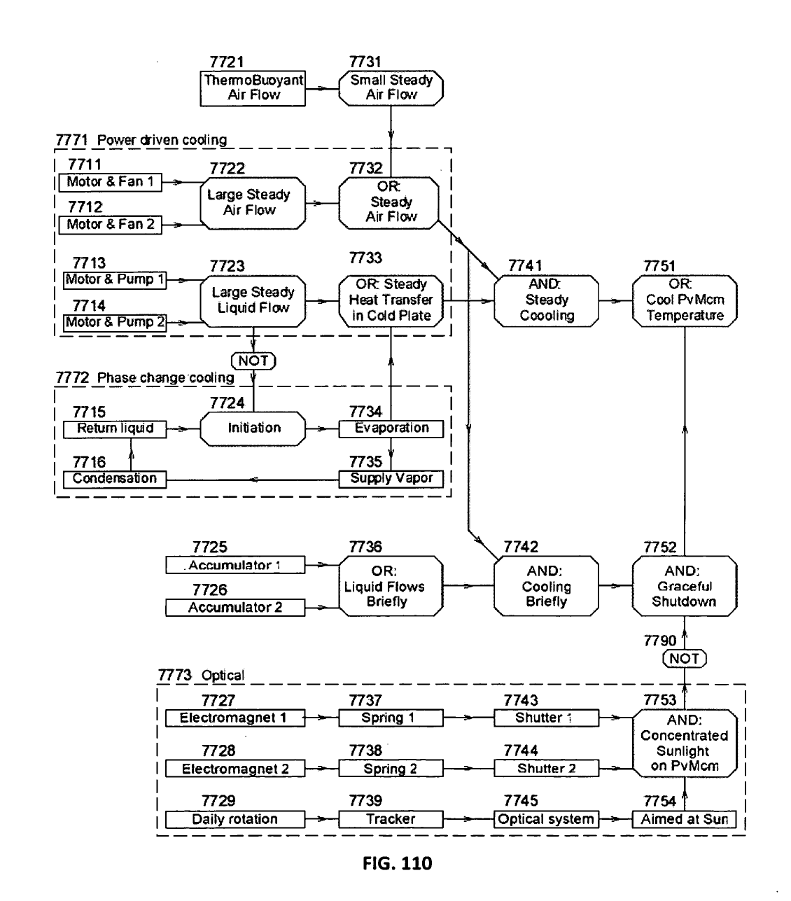

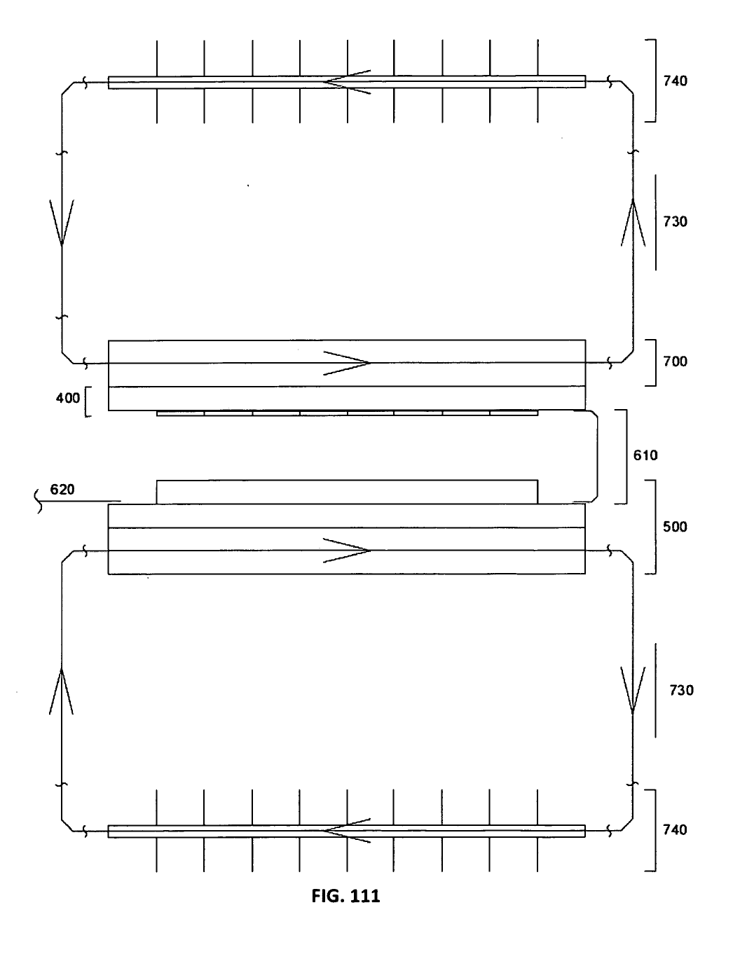

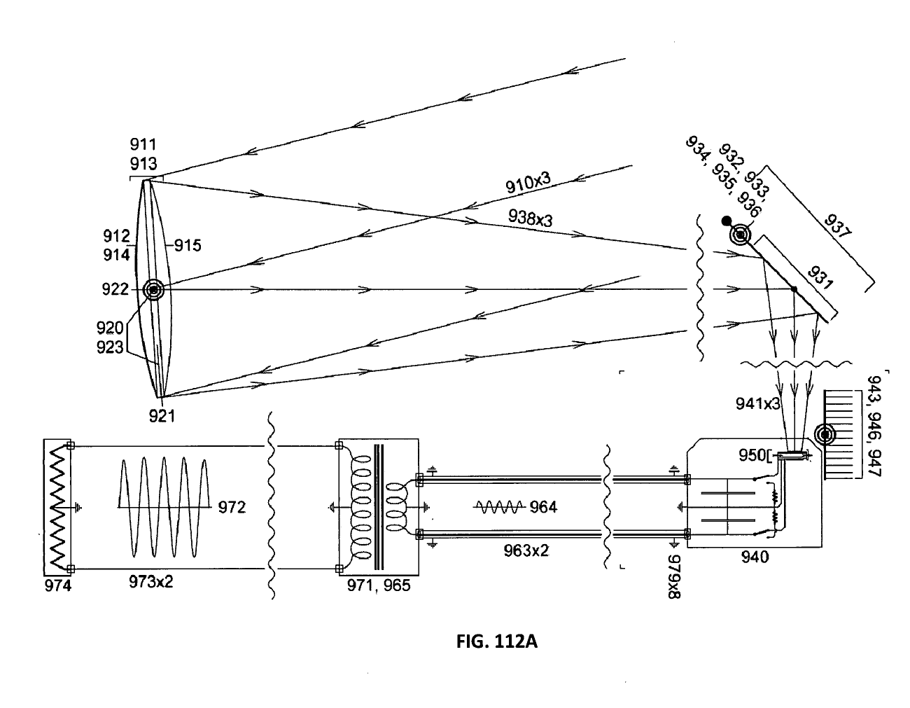

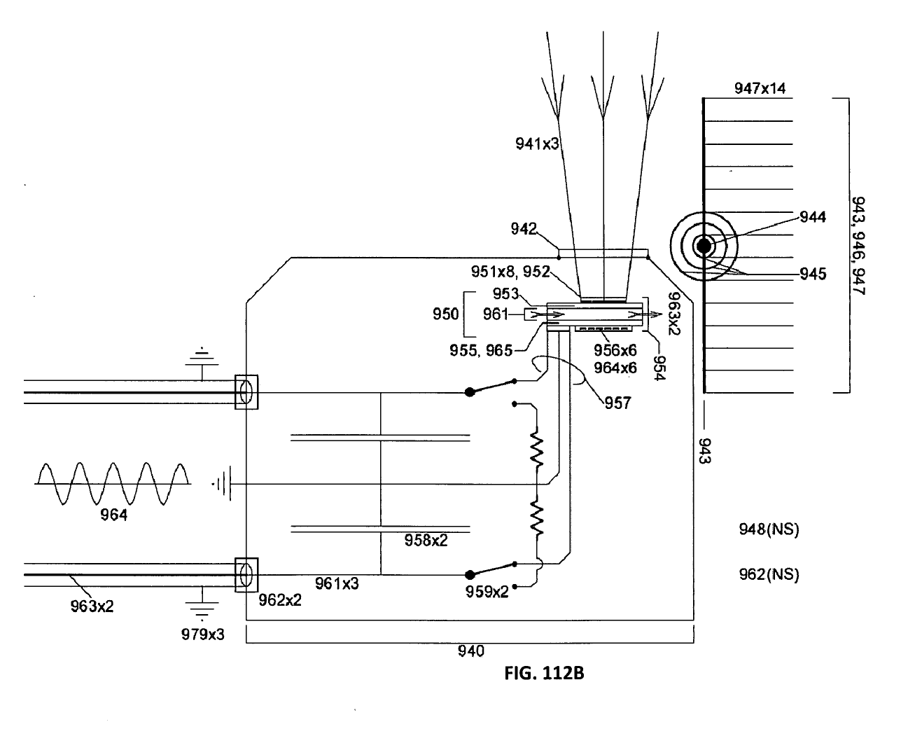

US patent application 2008/0135095; by Cummings & Moore; filed 2007 Aug. 24; and titled “Rigging System for supporting and pointing solar concentrator arrays”; particularly FIGS. 9 thru 17.

In their preferred embodiment, PV cells are mounted on a printed circuit board (PCB). This has printed copper wiring and plastic dielectric. For electrical and thermal conduction perpendicular through the PCB, there are drilled holes filled with copper plating and solder fill. For electrical insulation between high voltage and ground, there is a thin film of dielectric. There an array of 8*7 PV cells is soldered on a substrate with thermal vias. On the surface away from the PV cells, there is a plated metal layer for hydraulic sealing. Heat is removed by water jets impinging on the back of the substrate.

“Force Fed Boiling and Condensation for High Heat Flux Applications”, by E. Cetegen, S. Dessiatoun, M. Ohadi at Univ. of Maryland. This was presented at the “VII International Seminar on Heat Pipes, Heat Pumps, Refrigerators, Power Sources”, in Minsk, Belarus on 2008 Sep. 8-11. This combined micro-grooved heat-transfer surfaces, pump-driven flow, boiling and evaporation, refrigerant fluid.

US patent 2008/0060636; by Tuchlet; filed 2007 Sep. 24; and titled “Solar Energy Controller” The preferred embodiment is a shutter to control sunlight onto a solar-thermal receiver. There is liquid cooling inside each blade of this shutter.

### Known Structures for Electrical Packaging

U.S. Pat. No. 4,777,060; by Mayr et al.; and titled “Method for making a composite substrate for electronic semiconductor parts”. This uses a very high temperature process, such as chemical vapor deposition or plasma-spraying, to deposit a ceramic dielectric on a refractory metal core, such as AlN on Mo.

U.S. Pat. No. 6,713,862; by Palansiamy et al; and titled “Low Temperature co-fired ceramic-metal packaging technology”. That uses a less high temperature (“low temperature”) process; and can fabricate multi-layer ceramic wiring plus thermal vias.

US patent application 2003/004744; by Boxman et al; assigned to Trans Arc; and titled “Vacuum arc plasma gun deposition system”

US patent application 2005/0072461; by Kuchinski, Martin & Mukerjee; not assigned; and titled “Pinhole porosity free insulating films of flexible metallic substrates for thin film applications”

U.S. Pat. No. 6,174,583; by Yamada et al; assigned to NGK Insulators; and titles “Aluminum nitride sintered body, metal including member . . . and method . . . . ”. This teaches structures and fabrication methods for an electrostatic chuck, including an aluminum nitride dielectric body that contains a molybdenum metal plate.

### SUMMARY OF THIS INVENTION

This teaches a solar receiver and system for power generation from very highly concentrated sunlight. This provides advantageous capital cost versus output power. Compared to relevant prior art, this provides advantages in: use of higher solar concentration on a dense array of PV cells; generation of higher output power per solar receiver (scalability); closer unification of PV cells and electrical inverter circuits; manufacturability. This provides advantages in: cooling and packaging for electrical power devices; electrical circuit impedance; low frequency and high frequency electrical properties. A preferred embodiment is as follows.

A Photo-voltaic Many Cell Module (“PvMcm”) includes a large substrate with many photo-voltaic (“PV”) cells mounted in a dense array. This substrate has a core of solid molybdenum, insulated on both faces with aluminum nitride. Atop this is one layer of molybdenum printed wire. This electrically connects the PV cells. Atop this is another dielectric layer. This substrate provides excellent thermal resistivity.

This receiver also includes a Switch Many Chip Module (“SwMcm”) to convert DC to AC electrical power. This includes a second substrate that carries power switches mounted tightly on one surface. This substrate includes a metal core, ceramic insulation and several layers of printed wiring.

A cold-plate provides water cooling for both the PvMcm and SwMcm. This can amply cool 100 W/cm̂2 heat flux throughout the PvMcm. Also this improves inverter reliability, which otherwise is a problem for PV power generation. There is redundant protection against overheating. Along the optical path for sunlight, there is a shutter that is interlocked with cooling. This shutter can allow or else rapidly prevent highly concentrated sunlight on the PvMcm.

A relatively small enclosure tightly surrounds the PvMcm, SwMcm, and cold-plate. The PvMcm feeds DC power through a ribbon-like jumper to the SwMcm. In the PvMcm, jumper and SwMcm, the power wires and the ground planes form transmission lines with very low reactive impedance across a wide band. Overall, this solar receiver generates stepped AC power that is delivered through balanced hot wires with a central ground.

### BRIEF DESCRIPTION OF THE DRAWINGS

Principal View, FIG. {101}: This elevation view shows the PvScm's (PV Small Cell Modules), the PvMcm (PV Many Cell Module), Power Switches, the SwMcm (Inverter Switch Multi-Chip Module), and the cold-plate. Other Figures are organized in several clusters. Within each cluster, there is considerable overlap between figures, and descriptions apply to all these figures.

Cluster: Plan Views of PvMcm: Each of these figures is a plan view of a PvMcm. FIG. {102} shows fully a PvMcm that has width for 14 PvScm's. This shows 4 grounded sectors. FIG. {103} shows fully a PvMcm with 4 floating (ungrounded) sectors. FIG. {104} shows a quarter of a PvMcm that has width for 48 PvScm's. This shows one sector. By comparison, the complete PvMcm has four identical sectors, and would NOT be graphically clear.

Cluster: Schematic Views of Electrical Power Circuits: Each of these figures is a schematic of the electrical power circuits for PvMcm and the SwMcm. FIG. {105} shows 2 sectors without any power switches. FIG. {106} shows 2 sectors and corresponding power switches. FIG. {107} shows 8 sectors and corresponding power switches.

Cluster: Views of Cooling: These figures show embodiments of the cooling subsystem. FIG. {108} shows the cold plate. FIG. {109} shows the cooling system external to the cold-plate. This can operate in plural modes, depending on the availability of external power. One mode is single-phase cooling driven by external power. Another mode is two-phase cooling that is independent of external power. FIG. {110} is a reliability block diagram for cooling. FIG. {111} is a variation, with separate cooling for the PvMcm and SwMcm.

Large-scale view, FIG. {112}: This shows items and relationship too large for other views. These includes: primary mirror, secondary mirror, enclosure, solar receiver, capacitor, transformer, HV lines, and load.

Cluster: More variations: Embodiments with gaps between PV cells. This cluster shows embodiments with significant gaps between PV cells. FIG. {120} shows a PvMcm with a widely spaced array of PvScm's. FIG. {121} shows an embodiment for sunlight at low to moderate concentration.

Graphics conventions: Several graphical conventions and styles are used to improve graphical clarity. These are familiar and readily understood by an engineer with ordinary skill in relevant fields.

Identical components may appear several times in a figure. The corresponding tag generally appears only once, optionally followed by a repetition count. The abbreviation “NS” represents “Not shown, but logically included”. For example in FIG. {101}, a PvScm appears 8 times, but its tag appears only once, as {300(8×)}. Also tag {430 (NS)} indicates that low-current components are not shown, but are logically included.

For graphic clarity, some adjacent components are shown artificially separated. For example, the PvMcm {400} and the cold plate {710} and the SwMcm {500} are separated in the Principal View, FIG. {101}.

In some figures for clarity, the height and width are shown with different magnifications within the same component, and between different components. For thin components and thin layers, the thickness is strongly exaggerated. An example is the PvScm {300} in the Principal FIG. {101}. For a large component, its image is contracted. For example, in FIG. {109}, the external heat exchanger {740} is shown greatly contracted compared to the cold-plate {710}.

For some components are represented as a symbol, rather than a physical image. An example is the power switches {520} in the Principal View, FIG. {101}. Another example is the circuit symbols in the Electrical Power Schematic FIG. {106}.

Each cluster provides plural closely related figures that: show parallel views of directly analogous embodiments; show the same symbols; use the same tags; use the same or analogous graphic style. Shared aspects of plural figures in a cluster are generally described by a unified text.

In a cluster, the figures may differ from simple to complex, in their embodiments, level of detail, graphical simplification. Also in a cluster, the figures may show different embodiments that provide analogous functions. An example is the cluster “Plan Views of PvMcm”, FIGS. {102}, {103}, {104}.

A component will appear in several figures in a cluster. It will have identical or closely analogous appearance in all these figures. The corresponding tag (reference number) will appear in only one figure. This tag is implied everywhere this component appears in other figures in the same cluster. An example is the PvScm {300} in “Cluster: Schematic Views of Electrical Power Circuits”, FIGS. {105}, {106}, {107}.

A cluster of figures is a much clearer alternative than an omnibus figure that attempts to show all components and all tags, in the most comprehensive embodiment.

### LIST OF REFERENCE CHARACTERS

Let “tag” mean a reference character for an item in a figure. Each component has the same tag wherever it appears in any figure, except for the reliability block diagram, FIG. {110} and its tags {7700}.

These tags are intended to clearly describe this invention. Therefore these tags and this list form a logical hierarchy or outline structure. In general, a tag ending in numeral 0 summarizes more detailed tags ending in numerals 1 through 9. Thus {400} summarizes {410} through {490}, and {410} summarizes {411} through {419}.

{100} Figures See above.
{200} Flows
   {210} SL (Sunlight)
   {211} Vector of SL
   {212} Region of uniform SL
   {213} Region of decreasing SL
   {214} Circular boundary of uniform illumination
   {215} Intensity of SL
   {216} Location of SL
   {219} Other
{220} Electrical power (E-pwr) vector
   {221} E-pwr vector for one PvScm
   {222} E-pwr vector, cumulative for successive PvScm's
   {223} E-pwr vector for all PvScm's
   {224} E-pwr vector for Stepped Alternating Current (S-AC)
   {225} Waveform for S-AC
   {229} Other
{230} Heat flow
   {231} Heat flow vector
   {232} Heat flow vector from PvScm
   {233} Heat flow vector from Power Switch
   {239} Other
{240} Coolant flow
   {241S} Supply liquid vector
   {242R} Return fluid vector
   {243R} Return liquid vector
   {244R} Return vapor vector
   {249} Other
{250} Mechanical motion
   {251} Linear motion vector
   {252} Rotary motion loop
   {259} Other
   {260} Gravity acceleration vector
   {290} Other
{300} PvScm (PV Small Cell Module)
{310} PvScm Structures
   {311} PV Cell direct on MCM
   {312} PV Cell on Scm (Small Cell Module) on MCM
   {313} PV Cells on Fcm (Few Cell Module) on MCM
   {319} Other
{320} PvSCM XY Features
   {321} PvScm with standard PV Cell
   {322} Special PvScm with triangular PvCell, 2L by 1L
   {323} Special PvScm, square with two triangular PV Cells
   {324} Special PvScm, saw-tooth with two triangular PV Cells
   {325} Special PvScm, with reflector
   {326} Chamfered Corner
   {327} Gap
   {329} Other
{330} PvScm Z Features
   {331} PV Cell
   {332} Fine wires on outer face
   {333} Substrate for PvScm, optional
   {334} Central Pad
      {3341} Central Pad, Die Bot
      {3342} Central Pad, SCM Top
      {3343} Central Pad, SCM Bot
   {335} Side Pad
      {3351} Side Pad, Die Top
      {3352} Side Pad, Scm Bottom
   {336} Wiring & insulation
   {3361} Via through PV Cell
      {3362} Via through SCM Body
      {3363} Wrap around W&I
      {3364} Gull-wing W&I
      {337} Auxiliary electronics
         {3371} By-Pass Diode
         {3372} Sensor for voltage & temperature
         {3373} Local transceiver
   {338} Local Bond, from PvScm to PvMcm
   {339} Other
   {390} Other
{400} PvMcm (PV Many-Chip Module)
{410} PV Mcm Ss (Substrate)
   {411} Dielectric & printed wiring, on outer face
   {412} Core, also is ground plane
   {413} Dielectric, on inner face
   {414} Global interface to Cold Hat
{420} Sector
   {421} Pair of sectors
   {422} Positive sector
   {423 } Negative sector
{430} Sector hot wire
   {431} Hot wire for positive sector
   {432} Hot wire for negative sector
   {433} Short segment of hot wire
   {434} Continuous line representation of hot wire
   {435} Additional wire in slight gap, for floating half-sector
   {436} Gap between adjacent PV cells
{440} Ground plane
   {441} Ground wire implicit in ground plane
   {442} Ground via from power wire layer to ground plane
   {443 } Ground via at center of PvMcm
{450} DC Terminal
   {451} Ground terminal
   {452} Positive terminal
   {453} Negative terminal
   {454} Connector for sector
   {490} Other
{500} SwMcm (Electrical Power Inverter Switch Many-Chip Module)
{510} SW Mcm Substrate
   {511} Dielectric & printed wiring, on outer face
   {512} Core, also is ground plane
   {513} Dielectric, on inner face
   {514} Global interface to Cold Plate
   {519} Other
{520} Power switch
{530} High-current components
   {531} Connector for DC Sector
   {532} Hot wire for DC Sector
   {533} Ground wire for DC Sector, implicit in ground plane
   {534} HF Capacitor, integrated with substrate
   {535} HF Capacitor, discrete
   {536} Hot wire for S-AC Phase
   {537} Ground wire for S-AC Phase, implicit in ground plane
   {538} Connector for S-AC Phase
{540} Low-current components
{590} Other
{600} Jumper
{610} Jumper
   {611} Positive
   {612} Ground
   {613} Negative
   {614} Signal
{620} S-AC (Stepped Alternating Current) Cable
   {621} Hot wire
   {622} Ground sheath or wire
   {623} Connector
{630} Downstream Components
   {631} LF Capacitor
   {632} Transformer
{690} Other
{700} Cooling
{710} Cold-plate
   {711} Outer wall=PvMcm
   {712} Heat transfer surface=Inner surface of the PvMcm
   {713S, R} Internal manifold for supply and return
   {714S, R} Internal conduits for supply and return
   {715S, R} Supply inlet, return outlet
{720} Enhancements inside Cold Plate
   {721} Nozzle sheet
   {722S} Jet, impinging
   {723R} Jet, splashing away
   {724} Fins and grooves
   {727} Wick
   {728} Evaporator
{730} Circulation for coolant fluid
   {731S, R} Bellows for supply and return fluid
   {732S, R} Tubes for supply and return fluid
   {733} Hydraulic pump
   {734} Hydraulic accumulator
   {735} Volume compensator
{740} External heat exchanger and condenser
   {741} Air Fins
   {742} Inside surface
   {743} Enhancement features
   {744} Internal fins
   {745} Internal manifold
   {746} Condenser
{750} External air
   {751} External air, thermo-buoyant flow
   {752} External air, fan-driven flow
   {753} Fan
   {754} Motor
   {755} Large sun-shield (NS)
{760} Reflection
   {761} Reflective shield
   {762} Reflective coating
{770} Reliability block diagram
   {7701} Motor & Fan 1
   {7702} Motor & Fan 2
   {7703} Pump 1
   {7704} Pump 2
   {7705} Thermo-Buoyant Flow
   {7706} Accumulator 1
   {7707} Accumulator 2
   {7708} Interlock
   {7709} Shutter
   {7710} Tracker
   {7721} OR: Ample Air Flow
   {7722} OR: Air Flow
   {7731} OR: Steady Liquid Flow
   {7732} OR: Liquid Flow
   {7733} AND: Cooling
   {7734} OR: PvMcm Temperature
   {7741} OR: Protection Available
   {7751} AND: Prevents Concentrated Sun Light
   {790} Other
{800} Miscellaneous
{810} Enclosure
   {811} Case
   {812} Window for Sunlight to enter
   {813} Portal for S-AC Cable or DC Jumper
   {814} Ground strap from Case to SwMcm and PvMcm
{820} Embodiment: PvMcm with wide gaps between PvScm's
   {8201} Gap between PvScm's
   {8202} Wiring in gap between PvScm's
   {8203} Optical concentrator for individual PvScm
   {8204} Optical homogenizer for individual PvScm
{890} Other

### OVERVIEW

Definitions: It is helpful to read these definitions together with the Principal View, FIG. {101}. To harvest sunlight into electrical power, consider a solar power farm with one or more solar power systems. Each system includes a solar collector and a photo-voltaic (“PV”) receiver. Let “standard sunlight” be defined as 1.0 kW per M̂2 of sunlight perpendicularly onto a solar collector. This is representative of the solar flux at mid-day on a clear bright day, through a standard atmosphere. Let “granularity” be defined as the electrical output power from one solar power system under standard sunlight. Let “normalized cost” be defined as the capital cost per solar power system, divided by its granularity.

High concentration: This invention is designed to achieve very small normalized cost for solar PV power generation. The concentration of sunlight reciprocally scales the ratio of nominal output power divided by the area for the PV cells. This invention preferably uses very high concentration. This scales down the normalized cost for PV cells, and thus economically justifies PV cells with very high efficiency.

However, very high concentration generates intense heating and needs intense cooling. Concentration reciprocally scales the ratio of nominal output power divided by the area of electronic packaging that is closely coupled to the PV cells. Very high concentration scales down the normalized cost of electronic packaging. This economically justifies advanced packaging and materials, particularly molybdenum and aluminum nitride. These have excellent thermal, thermo-mechanical and dielectric properties. Also this economically justifies intense liquid cooling, which can remove intense heat flux and large total heat.

Large granularity: Consider the normalized cost for each of these subsystems: optical and mechanical (“opto-mechanical”) subsystem; tracking subsystem; cooling subsystem (cooling beyond the electronic packaging); cables and connectors; infra-structure. For each such sub-system, consider embodiments and capital cost as a function of the output power per system (granularity). For these, the subsystem capital cost increases slower than the nominal output power per system. As a useful approximation, each such normalized costs scale roughly as the inverse square root of the granularity. This invention strongly uses increasing granularity to reduce normalized costs and to improve feasibility. Large granularity and high concentration together economically justifies aggressive liquid cooling, which can cool intense heat flux and very large total heat. Such cooling does not constrain the maximum feasible granularity. This invention facilitates embodiments with very large granularity. Its embodiments are economically marginal at 3 kW, very good at 18 kW, excellent at 72 kW, and more.

Counter-example: Compared to this invention, the relevant prior art generally uses less efficient PV cells, electronic packaging with less cost per area, less aggressive cooling, and smaller granularity. Such technologies may work well for lower concentration and considerably smaller granularity. Such technologies constrain increasing concentration and increasing granularity, and are constrained thus constrain increasing use of the above advantages.

Context: This invention applies to a clear bright climate, where a solar PV farm provides scheduled maintenance. An opto-mechanical subsystem concentrates sunlight ˜1,000×. Thus standard sunlight is concentrated to a flux of ˜100 W/cm̂2, which feeds a solar receiver. The following is a preferred embodiment of this invention.

PV cell: Highly concentrated sunlight illuminates a high efficiency PV Cell, with three diodes layers in series on the surface of a germanium chip. Compared to the concentrated sunlight (100%), this produces ˜40% electrical power and ˜60% heat. The PV cell and closely related hardware (such as a bypass diode) are attached directly to a large substrate (see below concerning PvMcm).

Typically, each PV cell has effective area about 1 cm̂2. A PV cell generates ˜15 Amps at ˜2.5 Volts during standard sunlight and nominal operating conditions. The conditions include suitable cell temperature and suitable load. These are rounded representative values, and will be used throughout these descriptions. By contrast, the exact values depend on many specifics, including cell temperature and load impedance

PV Small Cell Module (PvScm): In another embodiment, a PV cell and bypass diode are mounted on a small substrate, to form a distinct PvScm. This small substrate is approximately congruent with the PV cell, and preferably has Coefficient of Thermal Expansion (CTE) approximately equal to the PV cell, and preferably is very thermally conductive. Each PvScm or PV cell is attached to a large substrate (see below).

PV Many-Cell Module (PvMcm): A very large embodiment is as follows. There are ˜1,800 PvScm's or PV cells. These are mounted on a large high power printed wire substrate with area about (60 cm) by (60 cm). These PvMcm is formed by this substrate and these PC cells or PvScm's.

The PvScm's are located in a large dense array that approximates a solid disk. This is uniformly illuminated by highly concentrated sunlight. This array is electrically connected as 4 DC full sectors. Each has ˜450 PvScm's connected in series. For each sector, its mid-point is grounded, but this has relatively little current flow. During standard sunlight and nominal operating conditions (see above), each DC sector generates ˜15 A from +600 V to Ground to −600 V. This is equivalent to (18 kW)=(1.2 kV)*(15 A) at DC source impedance of (80 Ohms)=(1.2 kV)/(15 A).

All voltages are within 600 V of Ground, which is important for safety.

This substrate has a core layer of Mo metal, plus a ceramic dielectric layer on each face. Also, there is a one layer of metal printed power wires. The electrical insulation is safe for at least 1.2 kV. The printed wire cross-section is safe for at least 15 Amps/wire.

Because of the dense array, each DC sector has a relatively short total wire length. This proportionally reduces wire resistance and inductance.

Each power wire and the metal core approximate a transmission line, of the micro-strip style. This provides reactive impedance far less than the DC source impedance, 80 Ohms.

Analogous wire features and wire parameters apply to other parts of this invention. These include: current capability, high voltage insulation, and short length, circuit symmetry around ground, transmission line and reactive impedance.

Jumper: The PvMcm feeds DC power into a jumper. This provides transmission lines, with wire features and wire parameters as described above.

Switch Multi-Chip Module (SwMcm): The jumper feeds power into a SwMcm. This converts (“inverts”) the power to Stepped Alternating Current (“S-AC”) that is a stepped approximation or pulse-width modulated approximation to a sine-wave at 60 Hz or another frequency.

The SwMcm has semiconductor switches that can very rapidly switch power on and off at 15 A and 1.2 kV. Each switch includes a pre-amplifier/driver just upstream of its control electrode (gate). Thus each switch transition is very fast, and its energy dissipation is small, in spite the intense power flowing through each switch.

These switches are mounted on another large high power printed wire substrate. This has a metal core and insulation, plus several layers of printed metal power wires. This has wire features and wire parameters as described above. Also there is hardware for logic and timing to determine when to move each switch. This adjusts the AC timing to coordinate with the AC Grid.

During switch transitions, current in a wire will change with a very large derivative. This interacts with inductance in the wire, and generates a voltage spike. (The corresponding equation is: V=L dI/dt.) A voltage spike can interact with discontinuities with the wiring, and cause reflections, etc. In many case of the prior art, voltage spikes greatly stress switches, capacitors, diodes, PV cells. This degrades reliability, which is a significant problem.

This invention prevents this problem as follows. In Fourier analysis of AC circuits, inductors and capacitors have produce voltages with opposite phase. Thus a capacitor can counter-balance an inductor. In the instant solar receiver, the PvMcm, jumper, SwMcm, the power wires have significant capacitance. This counter-balances their inductance. Thus wiring in this receiver approximates a transmission line for power. Across frequencies from DC to HF, this has extremely small characteristic (reactive) impedance. Therefore the unbalanced inductance is tiny. This prevents or greatly reduces voltage spikes, and significantly facilitates reliability.

In a representative embodiment, the circuit topology is 4 DC Sectors. This power is inverted to 3 or 6 S-AC phases. Ground is connected to the mid-point of each DC sector and each pair of S-AC phases. However the ground carries relatively little current.

These S-AC phases together are symmetrical about ground. This provides higher effective source impedance compared to an analogous system that uses ground for major current. Cable resistance dissipates a fraction of the generated power, often called ohmic losses. As a simplification, this fraction scales with the ratio of the cable resistance divided by the DC source impedance. Thus higher DC source impedance reduces this dissipation fraction. As explained in a later section, higher DC source impedance also provides advantages concerning high voltage safety and insulation.

Cold-plate: This provides cooling for high density heat through a small temperature drop. In a first mode, heat is removed by a single-phase liquid. This is circulated by a pump. To improve heat transfer, there are many tiny liquid jets that impinge on the inner surface of the cold-plate. A second mode has small fins and grooves on the inner surface to improve heat transfer. In these two embodiments, liquid flow is generally activated by pumps.

Cooling system: This cold-plate provides cooling on two large outer surfaces. Inside the cold-plate is a hydraulic manifold. This provides geometrically controlled in-flow of supply fluid, and geometrically controlled out-flow of return fluid. (In one-phase cooling using water, this supply fluid is cooler liquid water, and the return fluid is warmer liquid water. In two-phase cooling with water, these are respective liquid water and vapor water.) The flow of cooling fluid on the heat transfer surface(s) is highly parallel. On the heat transfer surface(s), the pattern of fluid is designed to match the pattern of heat density through this surface.

A third mode uses supply liquid and return vapor. Flow is a thermo-siphon, activated by evaporation, condensation and gravity. A fourth mode uses a metal wick inside the cold-plate. Thus flow is a heat-pipe, activated by evaporation, condensation, and capillary action. A sixth mode uses single-pass evaporation for short-term transitional cooling when the liquid region is ruptured.

For a large system, the preferred embodiment combines several of these modes. When external power is available, it uses pumped flow. When external power is not available, it uses thermo-siphon flow. It uses single-pass evaporation when there is a major rupture.

In the preferred embodiment, the PvMcm forms one large wall of the cold-plate, and the SwMcm forms or is thermally attached to another large wall. Thus these share the cold-plate and cooling system. This can very easily cool 60 W/cm̂2 of heat, while 40 W/cm̂2 is harvested as electrical power. Furthermore, when the electrical output is interrupted, there heating is 100 W/cm̂2. The cold-plate can cool this easily.

Cooling and reliability: This system provides excellent reliability against severe overheating and damage to the PV cells, PvScm's and PvMcm. There are a shutter and other features to enable graceful shutdown. Fan-drive air cooling is backed-up by thermo-buoyant air cooling. For single-phase liquid cooling, there are two pumps, plus at least one hydraulic accumulator.

Substrate materials: In the PvMcm, the substrate has a core layer of Mo, dielectric layers of AN, and a printed wire layer of Mo. This provides excellent thermal conduction from each PV Cell, through the Substrate, into the Coolant. Nevertheless this provides excellent high voltage insulation. Also, all these materials and the PV Cell have similar values for their CTE (Coefficient of Thermal Expansion). This minimizes thermo-mechanical stresses, and thus prevents mechanical fatigue and cracking Also this Substrate is mechanically strong, and is a reliable hydraulic barrier.

The SwMcm has several layers of printed wires and dielectric. However, the average heat flux is considerably smaller than the PvMcm. Therefore the temperature rise in the SwMcm is rather small. Also the cold-plate cools the SwMcm, its switches, and adjacent capacitors. Therefore these operate at cool temperatures, which enhance reliability.

Downstream: The SwMcm feeds multi-phase S-AC power through a short cable, to large power capacitors. These filter the current waveform, and partly smooth out harmonics of the line frequency. These provide multi-phase power with a better wave-form. This drives another power cable and feeds a transformer. This provides additional filtering, and also may change the voltage.

### Principle View of the Preferred Embodiment, FIG. {101}

Referring to FIG. {101}, an example embodiment is illustrated that includes highly concentrated sunlight {211}, many PV Small Cell Modules (PvScm's) {300}, a PV Many Cell Module (PvMcm) {400}, a DC jumper {610}, an inverter Switch Many Chip Module (SwMcm) {500}, and a cold-plate {700}.

For sunlight measured in the plane of the PvScm's {300}, a graph shows its intensity {215} versus transverse location {216}. The intensity is uniform over a central region {212}, but decreases rapidly in the surrounding region {213}. Between these is a rather sharp boundary {214}.

The PV Many Chip Module (PvMcm) {400} carries many PvScm's {300}, each bonded to a large high-power printed wire ceramic substrate {410}. Highly concentrated sunlight {211} uniformly illuminates all PvScm's. Each includes a PV cell, where sunlight generates intense electrical power {221} and intense heat {232}. Through printed wire {411, NS} on the substrate {410}, these PvScm's {300} are electrically connected in series. Each successive increases the electrical voltage and cumulative electrical power {222}. A “strip-line” transmission line is formed by each power wire {430} and the core {412} of the PvMcm.

The PvMcm substrate {410} includes a molybdenum metal core {412} with two faces. Each carries a layer of aluminum nitride (AlN), a ceramic dielectric with very high thermal conductivity. On one face, this dielectric carries printed power wires {411} and solders bonding pads.

The preferred embodiment does NOT have electrically conducting vias that penetrate the core. Only the first face is used electrically; the second face is not. However both faces have ceramic dielectric and wire. This provides mechanical symmetry, balances stresses, and prevents warping, and cracking

The overall electrical power (“E-pwr”) {223} feeds through a DC Jumper {610} to the SwMcm {500}. This includes another large high power printed wire substrate {510}. This carries a number of fast power switches {520}, plus other high current components {530} and low current components {540}. These convert (“invert”) the overall E-pwr {223} into Stepped Alternating Current (S-AC), indicated by E-pwr vector {244} with a representative voltage waveform {245}. This feeds through an S-AC Connector Pair {621} to an S-AC Cable {622}.

The PvMcm {400} and the SwMcm {500} each thermally connect through a global interface {414}, {514} to the Cold Hat {700}. Intense sunlight {211} deposits intense heat {232} into each PvScm {300} and the PvMcm {400}. This heat {232} conducts through the PvScm {400}, through the PvMcm substrate {410}, and into the cold-plate {700}. Here heat is removed by a liquid coolant {240, NS}, preferably water. Also, each power switch {520} dissipates power as it switches rapidly and frequently. From each power switch {524}, this heat {233} conducts from through the SwMcm substrate {510}, and into the cold-plate {700}. Thus the PvMcm {400} and SwMcm {500} maintain cool temperature, even though they provide very considerable E-pwr {223}.

For graphic clarity, this figure has several graphical conventions. Thin components are drawn with exaggerated thickness. Some components are drawn “blown apart”. A long wiggly spline indicates the preferred embodiment is much wider than shown here.

### PV Small Cell Module, PvScm

In one embodiment, each PV cell is directly attached to the PvMcm substrate. Also a corresponding bypass diode is directly attached.

In another embodiment, each PV cell and a bypass diode are attached to a small substrate with high thermal conductivity and suitable CTE. These form a PvScm. For example, this small substrate is AN with printed wiring. The PvScm is attached to the large substrate of the PvMcm. Similar small modules are taught in the prior art, such as USP Application 2005/0072457 by Glen, titled “Solar Cell Structure with Integrated By-pass diode”.

Throughout this invention and its claims, wherever either “PV cell” or “PvScm” is written, let it be understood to refer to both embodiments, unless otherwise explicitly stated or implied by context.

In general, a PvScm is slightly larger than its PV cell. Since PV cells are generally square or rectangular, a corresponding PvScm {321} is square or rectangular. However, at the edge of the illuminated area, it is important to avoid a PV cell that straddles the illumination boundary. This requires specially shaped PV cells and PvScm's. In some locations, a triangular shape {322} matches the illuminated region, and nevertheless matches the area of a standard PV cell. At some locations, two small PV cells are connected in topological parallel {323}, and together these match the area of a standard PV cell.

### Substrate Specifics

Principles: The PvScm {300} and PvMcm {400} largely fulfill the following principles. The PvScm and PvMcm enable efficient and economical manufacturing. Every layer provides very small thermal resistance compared to its area (i.e. very small areal thermal resistivity). The dielectric layers provide very reliable insulation for the maximum voltage multiplied by a generous safety factor.

In the PvMcm substrate {410}, every layer has a Coefficient of Thermal Expansion (“CTE”) that is close to the CTE for the PvScm. Depending on the embodiment, this is the CTE for the PV cell itself, or the CTE for the small substrate of the PvScm. This CTE match greatly reduces thermo-mechanical stresses and related strains. Also, the PvMcm substrate has sufficient mechanical strength to greatly minimize bending and related strains. Since strains are greatly reduced, corresponding cracks are prevented.

The PvMcm substrate also provides a reliable hydraulic barrier. The substrate surface adjacent to the coolant is chemically compatible with (and resistant to) the coolant and cooling system. The outer surfaces of the PvScm and PvMcm are robust against ambient effects, particularly prolonged exposure to highly concentrated sunlight, humidity and salt.

Materials: The preferred embodiment includes the following materials. The dielectric layers are aluminum nitride (“AlN”). To modify grain boundaries and improve thermal conductivity, this preferably includes additives, such as yttrium or zirconium oxide or metal.

The core is molybdenum (“Mo”). The printed wire starts as Mo powder, which is screen-printed, then sintered into continuous wires. There are bonding pads on top of the PvMcm substrate and on the bottom of the PvScm. These pads are thin metal coatings, which are well known in electronic packaging. For example, there is an ultra thin chromium coat, then a less thin copper coat, then optionally other metal coats. The heat transfer surface has optionally has a very thin copper coat. The coolant is mainly water. Other chemical details are described in the cold-plate section.

Materials, properties and functions: The core is a plate of Mo, with thickness is ˜0.5 mm thick. Each dielectric layer is AlN, and its dielectric strength (breakdown electrical field) is ˜17 kV/mm=˜17E6 V/M. There are 3 dielectric layers. On the liquid-cooled face of the core, the AlN layer is ˜0.5 mm thick. On the sun-heated face of the core, the AlN layer is ˜0.3 mm thick. Next is Mo printed wire, then another AlN layer, thickness ˜0.2 mm.

These materials and layers fulfill or approximate all the above requirements. The PV cell includes three PV junctions fabricated as a stack atop a germanium (“Ge”) chip. For materials {Ge, Mo, AlN}, the corresponding CTEs are respectively about {5.75, 5.6, 4.6} E-6 per K. During uniform temperature changes, all layers expand or contract almost equally. Also, the total thickness of AlN on either surface of the core is ˜0.5 mm. This symmetry counter-balances various thermo-mechanical effects. For all these reasons, thermo-mechanical stress and strains are relatively small. This prevents cracking due to thermo-mechanical distortions.

For {Ge, Mo, AlN}, their bulk thermal conductivities are respectively {60; 140; ˜160} W per (M*K). During normal operation, a representative heat flux onto the PvMcm is 60 W/cm̂2=0.6E6 W/M̂2. This conducts perpendicularly through the substrate. The areal thermal resistivity (ThRy) due to the thicknesses of the AlN and Mo is about 10E-6 K per (W/M̂2), so the corresponding temperature difference is 6K=6 C. This is quite small and facilitates cooling the PV cells.

Between the printed wire and the core, the AlN dielectric is ˜0.3 mm thick, and so its breakdown voltage is ˜5.4 kV. This provides a large safety margin.

The 0.5 mm thickness of the Mo core provides ample mechanical strength to withstand external forces, and greatly minimize bending the dielectric layers. Also this provides a very reliable hydraulic barrier.

On the solar surface there is printed wiring and outer dielectric. The printed wires are preferably Mo. In another embodiment, the printed wires include copper and there is a thin copper coat on the heat transfer surface. These two copper layers are mutually counter-balancing.

After sintering, AlN adheres to AlN, but does NOT adhere to Mo. For a core with Mo, there are a number of holes through the core. Before sintering, AlN on one face contacts through each hole to AlN on the other face. Thus after sintering, the AlN forms a solid that envelopes the core. In spite of these holes, there is sufficient remaining Mo, so the core provides sufficient mechanical strength.

AlN is thermodynamically very stable and can tolerate prolonged concentrated sunlight. Exposed surfaces (such as bonding pads) of the PvMcm and PvScm optionally have additional coatings to further protect against UV damage and against chemical attack by humidity, salt or other ambient chemicals. Various such coatings are known in the prior arts of chemical engineering and electronic packaging.

In recent years, there has been considerable development of AN for electronic packaging. This has provided printed wiring, packages with metal cores, and efficient manufacturing technologies. One technological precedent is electrostatic chucks for the semiconductor industry. Some chucks have AlN dielectric, Mo internal electrodes, and diameter about 300 mm. An example is found in the prior art: U.S. Pat. No. 6,174,583, as cited above. Another technological precedent is multilayer ceramic substrates for electronics.

This preferred embodiment uses only one face for electrical wiring, and uses the other face for only mechanical and thermal purposes. This avoids the complications of insulation for electro-conductive vias that penetrate a metal core.

### Substrate using HTCC-M

The prior art of ceramics provides several suitable methods to fabricate the substrate for the PvMcm. For large-scale production, the preferred embodiment is High Temperature Co-Fired Ceramic with Metal core (HTTC-M), which is available commercially from several companies, such as NGK Insulators, Inc in Japan.

Fine grains of AlN with additives are used to cast into a “green sheet” of unfired ceramic. Then holes are punched for vias. A paste with Mo powder is applied through a mask, to define the printer wires and metal vias. Starting with a Mo plate, hole are drilled or punched as described above. Then layers are stacked and laminated together: AlN dielectric, Mo core, AlN dielectric with holes and printed wiring, outermost AlN dielectric. This stack is sintered by simultaneously: compressing the stack; applying a nitrogen atmosphere; heating to 1,600 to 1,800 C. Thus the stack sinters into a solid substrate. Such processes and structures are previously well known in the prior art of HTCC-M ceramic substrates for electronics.

After the substrate is cooled, then a mask is applied to define attachment pads. Through openings in the mask, very thin coats of chromium and copper are applied by sputtering. Using electrolytic plating, a thicker coat of copper is applied. Optionally, solder pre-coat is applied to these copper pads. Finally the mask is removed. Similar processes and coatings are well known in the field of ceramic substrates and printed circuit boards.

The section on Variations describes several other embodiments for substrate structure, materials and fabrication.

### Substrate with Prefabricated AlN

AlN is commercially available as a fully sintered ceramic plate. These circumvent the need for high-temperature sintering. This allows an embodiment and fabrication method which are convenient for small- or medium-scale production.

First, use pre-fabricated AlN plate and a core to make a substrate blank. Start with several thin plates of AlN. On a plate, one surface is metalized, to enable soldering to the AlN. Then this plate and a layer of solder are placed against the face of the core. Similarly, another plate and solder are placed against the other face of the core. This is heated in a reflow oven to form a solid substrate blank. Its layers are: AlN, Solder, Core, Solder, AlN.

Second, transform this blank into a competed substrate. Holes are drilled to provide ground vias. Powder metal is screen printed to define printed wiring and to fill ground vias. Atop this, an outer dielectric is applied. Then the assembly is sintered at a relatively low temperature, such as below 1,000 C. Thereafter metal coatings for solder pads are applied, as described above.

In one version, the metal powder and outer dielectric are suitable for sintering at a relatively low temperature. For example, the outer dielectric is a glassy ceramic. A precedent is the IBM factory in East Fishkill, N.Y., US which produced ceramic substrates using copper wiring and a glassy ceramic. The outer dielectric experiences relatively small electrical fields. This allows the outer dielectric to be relatively thin, and to have relatively poor thermal conductivity.

In yet another version, printed wires are plated onto the core, and the outer dielectric is a polymeric composite, such as described below.

It is useful to consider thermo-mechanical effects. At the temperature of solder solidification, there will be zero thermo-mechanical stress between the Mo and AlN. For {Ge, Mo, AlN} the respective CTE values are {5.75, 5.6, 4.6} E-6 per K. As substrate temperature decreases, the Mo will contract slightly more than the AlN. The AlN total thickness is symmetrical around the Mo core, which cancels out any tendency to buckle, bow or bent. Also the Mo is relative stiff, which further prevents bending. Thus the AlN will be slightly compressed and the Mo will be slightly stretched. For a brittle material such as AlN, this mild compression makes it more difficult to crack. Therefore this substrate will be mechanically stronger than isolated sheets of AlN.

The solder between the Mo and AlN will experience a shear force. In a plan view of this substrate, shear force is zero at the center, and increases linearly with the distance from the center. The largest shear will occur at largest radius from the center. These shear forces will vary during hot and cold cycles. This will eventually cause solder cracking, starting with the corners of the substrate. This implies a finite lifetime that depends on the temperature cycle, substrate diameter, solder thickness, and other parameters. To maximize lifetime for a given total area of PV cells, the preferred plan-view outline for a substrate is rounded, such as an octagon or circle, rather than a square.

The section on Variations describes other embodiments using pre-fabricated AN.

### PvMcm14 with Grounded Sectors, Plan View, FIG. {102}

Preamble: The PvMcm preferred embodiment has PvScm's located on a circular pattern with diameter about 48 PvScm's. This carries about 1,800 PvScm's. Therefore a plan view is graphically overwhelming, and thus obscures this invention. Instead, this is taught by FIG. {102}, which is a much smaller PvMcm. This simplification is graphically clear and understandable, but illustrates the features of the preferred embodiment. This description largely applies to FIGS. {103} and {104}.

PvMcm Features: This has only one layer of printed wire, plus the core as a ground plane. This avoids the need for additional layers of dielectric and power wires, with more complexity and thermal resistance.

PvScm's connected in series will share the same current. All PvScm's ought to generate equal electrical power. In case there is very unequal illumination, then power from brightly illuminated cells might cause reversed voltage, dissipation and overheating in a cell that is dimly illuminated.

To provide equal power generation during normal illumination, all PvScm's have the same area and same optical flux. Therefore all PvScm's are inside the circular perimeter {214} for uniform illumination.

A bypass diode (NS) is connected in parallel with each PV cell. The PV cell and diode are connected with opposite polarity. Thus, in case of severely non-uniform illumination and reversed voltage, the bypass diode will shut current that otherwise could cause overheating and damage.

All electrical power sectors {422}, {423} ought to should generate nearly equal voltages. Between sectors with the same polarity, this balance enables parallel addition of current. Between sectors with opposite polarity, this enables serial addition of voltage with symmetry around ground.

Therefore each sector has the same numbers of PvScm's. This is straightforward, for locations away from the diagonal radius. Along the diagonal radius, successive locations alternate between two sectors. More abstractly, this balancing converts a square structure with 4-fold symmetry into approximate 8-fold symmetry.

The above features preclude a PvScm at some locations, where it would preclude voltage balancing between two sectors, or preclude current balancing within a sector. One such location is adjacent to the center of the PvMcm. Another is where the diagonal radius interests the circular boundary {214} of the uniformly illuminated area.

Structure: FIG. {102} shows a PvMcm {400 with a PV array whose diameter is includes about 14 PvScm's. (This motivates the abbreviation PvMcm14.) This carries 144 PvScm's {300}, and most are standard square PvScm's {321}. This PvMcm also includes a Substrate {410}, DC power hot wires {431}, {432} and DC terminals {451}, {452}, {453}.

There are 4 DC sectors {421}. Each connects a quarter of the PvScm's {300} in a series circuit. Each such PvScm connects through a short segment {433} of a hot wire to the next PvScm. However, for graphic clarity, all these wire segments are represented graphically by a continuous thick line {434}, and each PvScm is represented by a superimposed diode symbol. Each full sector {421} includes a positive half-sector {422} and a negative half-sector {423}.

For each pair of sectors {421}, the ends of its series circuit connect to a positive terminal {452} and a negative terminal {453}. The mid-point of this series circuit connects at the center {442} to the core and ground.

A positive sector {422} has a positive hot wire {431} that goes directly to a {452} positive terminal located near a corner. A negative half-sector is analogous.

The core provides a ground plane that connects through a ground via {443} to the outer surface and its wires. This connects the ground end of each sector, and connects each ground terminal {451}. For the positive and negative sectors {421}, {422} both are grounded at the center {443}. There are additional ground terminals {442} in each corner. This layout can be wired using only one layer for power wires. (By contrast, some other layouts would require two layers for power wires, particularly because of topological reasons along the diagonals.)

There is approximate optical and electrical symmetry between the halves of each sector, and between their downstream circuits. Suppose that illumination is uniform, and all PvScm's are identical. Then this symmetry is almost exact for power at DC, and at line frequency. Therefore even harmonic frequencies have relatively small amplitude. Almost all current follows from positive to negative terminals, and very little flows through the ground terminals.

Several effects may cause asymmetry and ground current, but these are generally small effects. These may include non-uniform illumination, non-uniform dust on the PvScm's, fabrication non-uniformity in the PV Cells. There may cause relatively small unbalanced DC currents and voltages. Further downstream, in the SwMcm {500}, the inverter power switches {520} might have fine asymmetry in timing jitter. This may cause some unbalanced transients of ground current.

Several features minimize the root mean square (RMS) average current and voltage due to transients. The unbalance components will be a fraction of this. Thus the RMS value of unbalanced transients will be relatively small. Nevertheless unbalanced transients may be observable on an oscilloscope.

The boundary for uniform illumination is circular {214} and approximates the boundary of the PV array. It is less preferred to enlarge the illuminated region beyond the PV array, because that would increase the heat into the PvMcm. (Nevertheless, this might be done for optical uniformity.)

At some locations along the circular boundary {214}, a standard square PvScm {321} would unacceptably straddle the boundary. This would preclude current power balancing within a sector. Instead there is a special PvScm {324}, with a triangular PV cell. This triangle has the same area and generates the same power, compared to a standard square PvScm {321}.

PvMcm with 4 Floating Sectors, Plan View, FIG. {103}

In the PvMcm of FIG. {103}, each sector it has its own positive and negative terminals {452} {453}, and is electrically isolated from the ground plane and core {440}. Each sector does not electrically connect to the core. Instead each connects through the jumper {610} and SwMcm {500}. Those are visible in FIG. {101}, but not visible in FIG. {103}. Thus each sector “electrically floats”. This enables additional topologies and designs for an inverter.

Compared to FIG. {103}, in FIG. {104} the sectors are displaced slightly outward. Along a horizontal or vertical radius between sectors, there is a slight gap and an additional wire {435} to complete the sector. Thus floating sectors can be connected using a single power layer.

### PvMcm48, Quarter Plan View, FIG. {104}

FIG. {102} has already introduced most components and concepts necessary for FIG. {104}. Therefore this describes features which are distinct for FIG. {104}.

This PvMcm has a horizontal diameter with 48 locations for PvScm's, although only half are visible here. Each pair of sectors {421} has 221 PvScm's. This figure shows only one pair of sectors, and each PvScm is represented by its outline. The center of the PvMcm is visible near the lower-left corner of this figure, where there is a ground connection {443}.

To provide equal voltages, each sector {422} {423} has the same number of PvScm's. Along the diagonal radius (see above) between the center and corner, the PvScm's alternate between the two sectors. The center-most location (lower left corner in FIG. {104} does NOT have a PvScm, because that would preclude equal voltages between sectors.

For a given E-pwr output, it is desirable to minimize heat deposited into the PvMcm. Where a functional PvScm is absent, instead there is a reflector.

Also, the PvMcm has a reflective coating {762} (visible in FIG. {108}, but not shown in FIG. {104}). This covers most of the top surface, except for solder pads. For example, this minimizes solar heating at gaps between PvScm's, and minimizes heating into exposed areas of hot wires.

### E-Pwr Schematic for

### 2 Sectors without Switches, FIG. {105}

### 2 Sectors with Switches, FIG. {106}

### 8 Sectors with Switches, FIG. {107}

These figures show the schematic for electrical power at three levels of details, for three analogous embodiments. These will be described together, plus comments about their differences. Many components are analogous between these figures. For graphical clarity, for most such components, the tag is explicit in one figure, implicit in two others.

PvMcm: Highly concentrated sunlight {211} penetrates a window {812} in the case {811} of an enclosure {810}. The sunlight uniformly illuminates many PvScm's {300}. There are sectors, positive {422} and negative {423}, and each includes many PvScm's {300} connected in series, between a hot terminal, either positive {452} or negative {453}, and a ground terminal {451}. Each sector connects at one end to the ground plane {412}.

DC schematic: Sectors alternate in polarity, and together form a pair of sectors {421}. These sectors are equally illuminated and symmetrically loaded, as measured in the band around DC, and in the band including line frequency and its relevant harmonics. Thus there is very little current through the ground terminals, as measured in these bands.

For one embodiment during nominal operation, each sector generates about 15 A current at almost 600V compared to ground. Thus a pair of sectors provides 15 A at current, with total voltage almost 1200V, and has near-zero ground current. This provides about 18 kW of DC power, with DC source impedance almost (80 Ohms)=(1200V)/(15 A). Every wire is within 600V from ground, which is important for safety and insulation and related costs.

In North America (NA), the safety & insulation requirements are discontinuous at 600V. In the European Union (EU), requirements are discontinuous at 1,000V. Therefore an EU preferred embodiment includes more PvScm's, and provides almost 1,000 V. Thus the total voltage is almost 2,000V, and the DC source impedance is almost (133 Ohms)=(2000V)/(15 A).

This DC source impedance is relatively large. This is significant for high frequency (HF) design, as explained in a later paragraph. Also, this is significant for DC design, safety and economics, as explained in a later section.

Each sector, its PvScm's and hot wire (segments) plus the ground plane {441} together form wide-band transmission line, of the micro-strip style. This connects to DC terminals: ground {451} and either positive {452} or else negative {453}. A later section discusses high frequency design of these transmission lines.

Jumper and Cable: In FIG. {105}, a pair of sectors {421} feeds a DC Jumper {610} through a portal {813} in the case {811} of the enclosure {810}. The voltage difference from ground to each hot wire is approximately half that measured between the positive and negative wires. Beyond this figure, this DC Cable drives an Inverter and thus provides S-AC power.

In FIGS. {106} and {107}, each pair of sectors {421} feeds DC power from the PvMcm {400}, through a connector {454}, then a Jumper {610}, then a connector {531}, and into the SwMcm {500} in the same enclosure {810}.

SwMcm: This {500} has an array of fast power switches {520}. Each is a semiconductor device, with adequate parameters for current, voltage, transition time. A switch may be a power MOSFET, power IGBT or power SCR (power Metal Oxide Semiconductor Field Effect Transistor, power Integrated Gate Bipolar Transistor or power Silicon Controlled Rectifier) or other technology. The graphic symbol is an abstraction. Although the symbol resembles a mechanical switch in a can, it represents a vastly more modern switch.

Each switch has a gate {NS} that is driven by low-current devices {540, NS}. These include logic for control and timing, plus a pre-amplifier to provide a sufficiently strong input to the gate.

Each closed switch feeds power to a hot wire {532} and ground wire {537} which is implicit in the ground plane. These carry Stepped Alternating Current (S-AC). This is represented by a power arrow {224} and a symbolic waveform {225}. FIG. {106} shows S-AC with three Phases, analogous to AC with 3 Phases.

This power goes through an S-AC Connector pair {538} {623} into an S-AC Cable {620-A}. For HF design reasons, this includes a ground sheath {622}. This S-AC cable extends nearby to a large LF capacitor {631, NS} designed for high voltage. In the preferred embodiment, this capacitor is cooled by indirect liquid cooling. This reduces capacitor temperature and thus improves capacitor reliability.

Together with series impedance further downstream, this capacitor smoothes out higher frequencies, particularly harmonics of the line frequency, and thus provides a smoother waveform. This feeds through a three-phase AC cable {620-B}, which may be rather long. This feeds an inverter transformer {632, NS}. This provides high voltage AC power with a good waveform, suitable to drive a nearby load or to distribute through the power grid. The inverter adjusts timing of signals into the gates of the switches, and thus provides phase matching with the grid. Also the inverter provides Maximum Power Point Tracking (MPPT), by adjusting its input impedance to extract maximum power from the PV array.

Switching transients and high frequency (HF) design: Several definitions shall be useful. “Transition frequency” is defined as half the inverse of the transition time of a power switch. When a switch makes a transition, the HF transient is concentrated around this frequency.

A frequency range is “wide-band” insofar as it includes most of the spectral content of the switching transition. Impedance is “low” insofar as it is less, preferably much less, than the DC source impedance of a pair of sectors in the PvMcm.

In order to minimize dissipation, switch transitions are very fast, typically between 20 and 200 nano-sec. Therefore the current ramp (“dI/dt”) may be huge: 0.75 to 0.75) E9 amp/sec. With good HF design, the power circuit has very little uncompensated inductance. This prevents inductive voltage spikes and related effects due to “L dI/dt”.

To smooth the current ramp, the SwMcm provides filtering, including filtering of line-frequency harmonics. As measured at the terminal of the switch, for substantially all frequencies in the spectrum of the transition pulse, the characteristic impedance preferably is less than, and preferably significantly less than, the DC source impedance of the sector.

The first part of this filter is formed by a very wide area in the hot wire {532}, the ceramic dielectric, and the ground plane {533}. It is important to consider capacitance, inductance and propagation effects. Therefore this filter is simultaneously an integrated capacitor {534}, a distributed capacitor, and a transmission line.

Three parameters strongly facilitate the reactive impedance (of an effective transmission line in the substrate of the PvMcm or SwMcm) to be considerably lower than the DC source impedance. The first parameter is the large DC source impedance: 80 or 133 Ohms. The second parameter is the large width of the hot wire {523}, compared to the thickness of the ceramic dielectric. The third factor is the large dielectric constant of the ceramic insulator, such as ˜9 for AN. For example, the transmission line can have impedance of a few Ohms or less, compared to 80 or 133 Ohms DC source impedance. This greatly reduces voltage spikes related to inductance and current ramp.

Another part of this filter is one or more discrete HF capacitor(s) {534}, connected between each hot wire {523} and ground {524}. A discrete HF capacitor can provide far more capacity than an integrated capacitor. Thus a discrete capacitor can filter frequencies lower than those filtered by the integrated capacitors. A discrete HF capacitor should be located as close as feasible to each Switch. This counter-balances the length and series inductance of any intervening wires. (For discrete HF capacitors, their number and locations may vary from those shown in FIG. {106}. Liquid cooling and low temperature facilitates reliability of these capacitors.)

A third part is formed by the DC jumper {610}. This is a ribbon cable with a few layers. This includes very wide parallel conductors, separated by a dielectric. This should withstand the maximum voltage with a sufficiently large safety factor. For example, polyimide of appropriate thickness is a suitable dielectric. The width of the conductors compensates for the thickness of the dielectric. This provides another integrated capacitor {534}, or distributed capacitor, or transmission line, with wideband low impedance. At each end of the DC Jumper, the connectors {531}, {454} are engineered for wideband low impedance.

Another part of the filter is formed by the PvMcm power circuit, including the hot wire segments, the PvScm's, and the ground plane. This hot wire also is very wide. This is similar to the discussion above. This provides an integrated capacitor {534}, or distributed capacitor, or transmission line with wideband low impedance.

On the PvMcm, where the PV series transmission line intersects the ground, there may be HF back-termination. This provides adequate damping for the frequency band around the transition frequency. Nevertheless, this provides almost zero resistance in the band around line frequency. This is feasible with an RLC filter, including discrete or integrated inductors and capacitors.

More generally, this filter may include more components and/or various types of components. This can adapt the prior art integrated capacitors and printed wire transmission lines. The parts together provide a suitable filter.

In other words, the PvMcm, DC Jumper and SwMcm should be transmission lines with very low impedance over a wide band. Thus series inductance is amply compensated by parallel capacitance.

Similar features apply to S-AC wires {536}, {537} on the SwMcm {500}, and to the S-AC Connector {538}, {623}, and to the S-AC Cable {620}. Likewise, these should form a filter with low impedance in this wideband, as measured at the Switch terminal on the S-AC hot wire. Also the S-AC cable {620} includes ground sheaths {622}. These extend the low impedance transmission line to the large capacitor {631} and to the transformer {632}.

Inverter Switches: FIG. {106} shows a pair of sectors that provide DC power with a center ground. This feeds an array of 3* 3 switches. These produce S-AC with 3 Phases and a center ground. However this inverter switch structure embodiment is representative of a larger diversity within the scope of this invention.

This can adapt features from diverse DC to AC switched inverters. This can adapt the prior art for: reduction of total harmonic distortion; better control of output voltage, current or waveform, including use of capacitors or inductors; “maximum power point tracking” to improve power extraction from the PV array; more frequent switching to provide better waveforms; designs similar to a Class D amplifier; use of more or fewer switches.

There are many circuit topologies and circuit types that can convert (“invert”) power from DC to S-AC and hence AC. Many can be adapted to this invention. For such variations, this invention can provide advantages: very good cooling for its power switches and capacitors; relatively small inductance and large capacitance between the PV Cells and the Switches; considerable engineering freedom in the DC Jumper and the Sector wiring; avoidance of some intermediate hardware, such as macroscopic cables from PV array to switches, or a separate enclosure for switches.

### Larger PvMcm

FIG. {107} shows a larger embodiment. Most components, their tags and their discussions from FIG. {105} and FIG. {106} are equally applicable in this larger embodiment, even thorough they are not explicitly shown in FIG. {107}. Those include ground plane and ground wires, distributed capacitors, and HF properties. Thus it is sufficient to describe only features that are different for FIG. {107}.

This has 4 pairs of sectors {421}, including 4 positive sectors {422} and 4 negative sectors {423}. These drive 8 corresponding hot wires {532} in the SwMcm {500}. There are 6 S-AC hot wires {621}, and these feed S-AC with 6 Phases {536} and a central ground. This provides symmetry around ground, and provides more parallel flow and less inductance, compared to an S-AC Cable with 3 Phases and Ground.

This SwMcm can adapt a wide diversity of topologies and designs for inverter switches. The SwMcm wires {532}, {536} define an array with 6 times 9 nodes. FIG. {107} shows a fully populated array, with all 54 Switches {520}. Although this is simple, it is the “worst case”. Electrical power engineering provides many inverter topologies and designs that could be substituted here. For many such embodiments, the switch array is less populated.

### Inverter Features

Inverter features and advantages over the prior art: A relatively small enclosure encapsulates and protects the PV cells, PvScm's, PvMcm, SwMcm, and capacitor. This unification reduces capital cost.

Let “indirect liquid cooling” indicate “cooling by a liquid that does not directly contact the heated object”. In this invention, the inverter switches and capacitors are indirectly liquid cooled. A thermo-conductive dielectric (preferably AN) provides electrical insulation between coolant (preferably water with additives) and these electrical components. Thus these switches and capacitors are especially cool, and therefore are especially reliable.

In the circuits from PV cells to inverter switches, the total length is quite short. Thus DC resistance and AC inductance are both quite small. Also, these wires form impedance transmission lines with very low characteristic impedance (compared to the DC source impedance). For all these reasons, these circuits have extremely small unbalanced inductance (i.e. inductance not counter-balanced by capacitance). Therefore inductive voltage spikes (“L dI/dt”) are small. This greatly minimizes a stress on switches and capacitors that otherwise could degrade their reliability.

Since unbalanced inductance is so very small, this enables capacitor (s) to be corresponding small (i.e. have small capacitance). This reduces cost, and/or allows a superior dielectric and superior reliability. One example is polyimide film, and another is a ceramic with high dielectric constant.

Such small capacitance scales down the electrostatic stored energy (half*C*V̂2). This reduces the energy which might be discharged by a switch. This reduces a known mode for switch failure, and thus improves inverter reliability.

In the brief transition interval (20 to 200 nsec) when each switch changes state, the there is a brief mismatch in transmission line impedance. Because of the very short length of wires in from PV cells to switches, the electrical transit time is faster than this transition. Thus this transient interacts with the wires etc as unified components. This prevents various pulse effects. Also this facilitates filtering and wave-form smoothing by the capacitor(s).

One variation has 8 separate S-AC cables, each with 3 phases. Each full-sector feeds a small separated array of switches, and then feeds a separate S-AC cable. Another variation provides “maximum power point tracking”. The uses a capacitor(s) and modifies switch timing. Thus the switch array adjusts it input impedance to maximize the power from the PV Array.

Counter-example: These distinctive features contrast favorably with the prior art of PV solar power panels and inverters for similar output power

In the prior art, an inverters typically is located in separate enclosure. From the PV panels to the inverter enclosure, there is an exposed cable with connectors at each end. The separate enclosure, exposed cable, exposed connectors incur added costs compared to this invention.

In the prior art, the inverter typically is air cooled, located in a box with metal walls and without thermal insulation. In many cases, the PV system is located in a hot bright climate, and the inverter enclosure often is heated by direct bright sunlight. Thus inverter switches and capacitors often are quite hot. This degrades inverter reliability, which often is a significant problem in the prior art. By contrast, this invention provides an inverter with much cooler temperatures, and thus improves reliability.

In many cases of the prior art, the circuit from PV cells and panels to inverter switches is quite long. This circuit has significant unbalanced inductance (“L”). When a switch makes a transition, there is an intense but brief current ramp (“dI/dt”). In some cases, this causes large inductive voltage spikes (“L dI/dt”).

Across these long circuits, the propagation time for electrical signals is longer than the switch transition time (20 to 200 nsec). Therefore these voltage spikes travel and reflect throughout the circuit. These spikes cause voltages stress on switches and capacitors. This degrades their reliability and/or requires components with higher voltage rating and higher capital cost. By contrast, this invention greatly reduces or prevents such voltage spikes.

The prior art often fights such unbalanced inductance by providing a very large capacitance, located close to the inverter switches. This large capacitance stores a large electrostatic energy. Under unfavorable circumstances, this energy could be discharged (dissipated) in a switch, and thus damage the switch. This reduces inverter reliability. Also, to provide a sufficient capacitance in a small volume, in some cases a discrete capacitor often has a less favorable dielectric, such as an electrolytic capacitor. Such dielectrics incur diminished reliability. By contrast, this invention enables smaller capacitance, less stored energy, a better dielectric, and thus better reliability. Inverter features shared with prior art: This preferably uses features well known in the prior art of inverters for solar power. These include: elimination of certain line harmonics; Maximum Power Point Tracking (MPPT); Anti-Islanding.

The inverter in FIG. {107} has 6-fold electrical symmetry around ground. This can be used to eliminate line harmonics at frequency multiples of 2F and 3F, namely frequencies {2F, 4F, 6F, 8F . . . } and also {3F, 6F, 9F . . . }.

By control of switch timing and Pulse Width Modulation (PWM) waveforms, the inverter also eliminates other harmonic frequencies, such as multiples of 5F or 7F. Using MPPT designs, the inverter control circuits adjust the effective input impedance of its input impedance to extract maximum power from the PV sectors. Using Anti-Island designs, the inverter senses the presence or absence of AC power in the down-stream load. When the grid is turned off, then the inverter turns off.

### Enclosure, Safety, Electrical Symmetry

Enclosure and safety features: This invention provides distinctive high density cooling, and provides distinctive substrates for high voltage, high power density, and very low areal thermal resistivity. These pivotally enable generation of high power S-AC from very concentrated sunlight using a very compact solar receiver, including PvMcm, SwMcm, cold-plate.

This compactness enables encapsulation inside a small enclosure. This enclosure and internal sub-units are grounded with redundancy and with very small resistance (“hard grounded”). There is a dedicated ground connection with a very permanent connection at each end. This ground connection is independent of cable connection or disconnection. Also grounding is independent of the linkage condition and access panel, as described below.

Inside the enclosure, there are many safety features. There is a shutter-mirror which can block or enable sunlight onto the solar receiver. Another section provides more details. There is an access panel, controlled by a latch-lock and screws. There is a high power discharge resistor. When connected, this can discharge stored energy in the capacitor(s), etc. There is a high voltage switch which can connect or disconnect between the SwMcm, discrete capacitor(s), power cable and discharge resistor(s).

Also there is a mechanical linkage. This is made of dielectric materials and rigorously insulated. This controls the latch-lock of the access panel, the high voltage switch, and the shutter-mirror. This linkage extends from inside to outside the enclosure, and then to an optional electro-mechanical actuator for remote control. Also, this linkage can be safely operated mechanically by an operator outside the enclosure.

The linkage provides two conditions: prevent operation; enable operation; suitable for operation. When the linkage is moved to condition “prevent operation”, then successively: the access panel is locked; the shutter is closed; the solar receiver and capacitor are disconnected from power cable; and these are connected to the resistor. When the linkage is moved to condition “enable operation”, then successively: the solar receiver and capacitor are disconnected from the resistor; these are connected to the cable; the shutter is opened; and the access panel is unlocked.

The linkage and enclosure are mechanically interlocked. In condition “enable operation”, the access panel is locked. Thus the enclosure mechanically prevents human access or tool access near high voltage or electrical components inside the enclosure. Condition “prevent operation” is a prerequisite for internal access. After this, it is necessary to explicitly turn a captive screw and to explicitly open the access panel, in order to gain access inside the enclosure.

Counter-example 1 In the prior art for solar PV systems with equivalent output power, generally the concentration typically was far smaller. Typically the PV panels were far larger than the solar receiver of this invention. Those PV panels typically were unenclosed or in large enclosures. Human access typically was allowed near operating PV panels, which complicated high voltage safety. Also, the normalized cost typically was significantly more costly, including PV cells, PV panels, inverter, cables and enclosures.

High voltage and safety codes: Electrical safety codes require correspondence between classes: the class of human access, including enclosure and interlocking; the electrical voltage class, as per the relevant safety code; the class of electrical insulation (plus isolation, grounding). In general, at a given voltage class, a looser class of human access requires a better class of insulation. In general, at a given insulation class, a looser class of human access requires a lower voltage class.

In North America (NA), the electrical safety requirements are discontinuous at 600 V DC. In the European Union (EU), electrical safety requirements are discontinuous at 1,000 V DC. In detail, high voltage safety requirements involve on many technical specifics and depend on the region. For clarity, this invention describes an embodiment for 600V, and may over-simplify some details. Where-ever a different voltage is relevant, that should be used instead. Likewise replace the number of PV cells in a sector, and the DC source impedance.

The output cable provides power through hot wires pairs with a center-tapped ground. Each pair carries stepped AC (S-AC) power that is symmetrical around ground. From each hot wire to ground, the voltage peak magnitude is slightly less than 600 V. The details of insulation and grounding fulfill the relevant safety code, so that this system is classified as “less than 600 V”. Even so, between a pair of hot wires, the voltage peak magnitude is slightly less than 1200V.

One embodiment is as follows. In the power output cable from the enclosure, around each hot wire is individually surrounded by separate insulation for at least 600V, then individually surrounded by a separate sheath. Each hot wire and its sheath have a separate connector to the solar receiver, and a separate connector to the transformer. All these sheaths are permanently and redundantly grounded with low resistance. This grounding is independent of cable connectors to the solar receiver or to the transformer. Human access or tool access near or to high voltage is prevented by the enclosure surrounding the solar receiver, and is prevented an enclosure surrounding the transformer.

Counter-example 2: Imagine a system with PV cells and PV panels enclosed in a large metal building with a large window. The building contains PV Cells and inverter switches that provide slightly less than (−600, 0, +600) volts, each measured from ground. Suppose this building is grounded, but allows human access. Thus every point is less than 600 V from ground, but the maximum voltage difference exceeds 600 V. However, because of possible human access inside this building, this counter-example requires safety features and insulation corresponding to 1200 V.

Impedance and electrical symmetry: The output power is provided by pairs of hot wires which are electrically symmetric around ground, such as DC at (−600V, 0V, +600V) or two-phase center-tapped AC. Thus the voltage from each hot wire to ground is only half of the total voltage difference.

Compared to the HV safety voltage benchmark (such as 600V), this electrical symmetry provides higher total voltage, and thus higher DC source impedance. This reduces ohmic dissipation in power wires and cables, and/or this enables thinner metal and less cost for wires and cables. High source impedance also facilitates HF design and reduced switching transients.

Consider a positive sector and a negative sector connected in series, with electrical symmetric around ground. Let “almost” be understood to mean “a little less than”. Each sector generates about 15 A at almost 1.2 kV. Thus power is almost (1.2 kV)*(15 A)=(18 kW), and DC source impedance almost (1.2 kV)/(15 A)=(80 Ohms). This impedance is 4× larger than a corresponding prior art, as described below. This higher impedance enables less ohmic dissipation in a given cable, and/or enables a less costly cable for the same dissipation.

More abstractly, this invention hereby teaches a PV system for power generation from sunlight. This includes a case that is grounded, a window where sunlight enters, and multiple PV cells. This generates current(s) and voltage(s) that are substantially electrically symmetrical around ground.

Counter-example 3: Consider the prior art of PV cells, panels and systems. In the prior art, all PV panels and DC power output cables typically have the same polarity compared to ground. Suppose each panel generates 15 A at almost 600 V. Thus two panels together provide 30 A and almost 600V. Together these provide almost (600V)*(30 A)=(18 kW) and DC source impedance is almost (600 V)/(30 A)=(20 Ohms).

### Background: Define Thermal Concepts

Consider steady state thermal conduction through a small volume. Each point [x,y,z] has a corresponding temperature T(x,y,z) The 3-dimensional derivative of temperature [dT/dx, dT/dy, dT/dz] is the “thermal gradient vector”. Heat power enters this volume perpendicularly through a small hotter surface, and equal heat power leaves perpendicularly through a small colder surface. Heat conduction is measured by a “heat flux vector” or “thermal conduction vector”. Its magnitude is the heat power divided by the area of the hot surface. Its direction is from the hot surface to cold surface. Often these definitions are applied using differential calculus, in the limit of a differentially small volume, etc.

Next consider steady state heat conduction from a PV cell. Incoming heat flux conducts: from the PV cell top face (top surface) to the bottom face; through a solder layer; through each layer (dielectric and core) of the substrate; to the heat transfer surface {712}. Here heat flux enters supply liquid, and is carried away by return fluid. At each point between these surfaces, there is a local thermal conduction vector. Heat conducts along a continuous curve (line), called a “thermal path”. At each point along this path, the path is tangent to the thermal vector at this point.

For each hotter location on the hotter surface, heat conducts along a thermal path to some colder location on the colder surface. This defines a correspondence from each hotter location to a thermal path. Also this defines a correspondence from each hotter location to a colder location.

Between corresponding locations, there is a “temperature difference”. “ThRy” is defined as the ratio temperature difference between corresponding locations, divided by the heat flux on the hot surface. ThRy is described as the “local thermal resistivity normalized by area”. This is typically shortened to “thermal resistivity”. ThRy has MKS dimensions of (K*M̂2)/W. This is equivalent to C per (W/M̂2). The “heat transfer coefficient” or “HTC” is defined as the reciprocal of ThRy.

Easy heat conduction is indicated by small ThRy and large HTC. Difficult heat conduction is indicated by large ThRy and small HTC.

For a given material, its “bulk thermal conductivity” or “thermal conductivity” is defined as the thermal conduction vector divided by temperature gradient vector. In an isotropic material, this is a scalar. This has MKS dimensions of W/MK, equivalent to W/M̂2 per C/M.

At an interface (mating surface) between two volumes, a ThRy value measures heat conduction across the interface.

### Background: Hot Spots and Thermal Non-Uniformity

Hot spots and thermal non-uniformity are a well-known problem in the prior art of cooling for power semiconductors. For example, this problem can strongly affect a semiconductor power chip with a solder bond to a heat sink. Because of improper technique during soldering, an air bubble may be trapped in the solder layer. This forms a disk-shaped void in the solder. This void has very poor thermal conductivity compared to the solder. When uniform heat flux is applied to the chip, there a “hot spot” compared to the remainder of the chip. This temperature difference is called the “temperature non-uniformity”.

In many cases, this is the result of a region with very poor thermal conductivity, such as a void in the solder. A nearby thermal path goes sideways and around this region. A thin PV chip or thin coating (e.g.: metallization) provides relatively poor thermal conduction parallel to its surface. From a PV cell location above the center of above a void, the corresponding thermal path includes a segment(s) of sideways conduction increases. This adds extra ThRy compared to other locations and thermal paths away from the void. This extra ThRy is called “thermal spreading resistivity”. (In other contexts, the “thermal spreading resistance” is defined as the temperature difference at hottest location divided by the total heat power into the PV cell.)

For a PV cell with a solder layer and a disk-shaped void with diameter that is significantly narrower than the chip thickness, the void generally causes relatively small thermal spreading resistivity. A disk-shaped void with diameter significantly larger than the chip thickness, the void generally will cause a larger non-uniformity in ThRy.

When uniform heat flux is applied to a chip adjacent to a void, there is a hot spot in the chip above this void. In many cases, the hottest location is above the center of the void. Here is the largest ThRy and the largest extra ThRy. The latter generally scales: inversely with chip thickness; inversely with bulk conductivity; as the square of the diameter of the void.

This extra ThRy is multiplied by the heat flux, and causes temperature non-uniformity. For example, the same void causes temperature non-uniformity: 15 C at 10 W/cm̂2; 45 C at 30 W/cm̂2; 150 C at 100 W/cm̂2. Thus non-uniformity is insignificant at low heat flux but serious at high heat flux.

For some chips, the hottest location on the chip determines the maximum allowable heat flux. This can readily be severely constrained by a void and its hot spot. Consider the ratio peak ThRy above the hot spot divided by ThRy far from the hot spot. Depending on various parameters, this ratio can be 2× or more.

This invention aims at a design space which is quite vulnerable to voids and thermal non-uniformities. This invention aims at very high heat flux, at least 60 W/cm̂2 and more. In 2009, the preferred PV cells are fabricated on germanium wafers just 0.2 mm thick. Germanium has thermal conductivity ˜60 W/MK, and silicon has ˜150 W/MK for silicon.

By contrast, prior art typically aimed implicitly or explicitly at considerably lower heat flux, using PV cells fabricated on thicker silicon wafers. Thus voids and other thermal non-uniformities often were allowed, tolerated or neglected by such prior art.

In discussion concerning thermal non-uniformity, let “thickness of a PV cell” be understood to mean “thickness of a PV cell or thickness of the small substrate for a PvScm”

### Substrate and Cooling

Cooling is relatively easy at low solar flux and low heat flux. Materials with modest thermal conductivity may be adequate. Cooling is relatively easy for a single PV cell or a small area of PV cells (such as less than about 3 cm by 3 cm). Sideway thermal conduction (heat spreading) may be helpful. Cooling is relatively easy for PV cells in a widely separated array. A special optical system may illuminate only the PV cells, and prevent illumination in larger areas between cells. Again heat spreading may be helpful. Cooling is relatively easy for small total thermal power. Air cooling may be adequate.

However these mitigations are limited. These are ineffective or inadequate for much more intense local heat flux (measured in a small area, such as a few square mm, or averaged across a chip), much more intense global heat flux (averaged across a wide and intense area of illumination), much larger total thermal power (many kilowatts or tens of kilowatts or more).

This invention is aimed at very different regime: very high solar flux, very high heat flux everywhere upon a solar power generation receiver, very large total power and total heat. Many PV cells are mounted in a dense array, illuminated everywhere with very highly concentrated sunlight, heated everywhere with very large heat flux, with very large total heat power. Thermal spreading and other mitigations described above are not sufficient or not effective in this regime. In this regime, cooling is a far greater challenge. To achieve adequate cooling, this invention teaches many novel cooling features, starting with the substrate. In electrical engineering, a substrate and its bonds (such as solder) typically serve mainly electrical functions, such as wiring topology, DC & AC wiring parameters, plus means for electrical attachment. Typically, thermal properties are minor functions.

Representative values: For this invention by contrast, the substrate and its bonds provide a very important thermal function: to conduct heat from the PV cell or PvScm to the fluid coolant. For the preferred embodiment, representative parameter values are as follows:

| Layer | Material | Thickness | Th. Cond'ty | ThRy |
|---|---|---|---|---|
| Units | NA | M | W/MK | K per W/M\hat{ }2 |
| Scale Factor | NA | E-3 | E0 | E-6 |
| PV Cell | Ge | 0.200 | 60 | 3.3 |
| Bond | Tin | 0.025 | 67 | 0.4 |
| Dielectric | AlN | 1.000 | 150 | 6.6 |
| Core | Mo | 0.500 | 140 | 3.6 |
| Jets Impinge | Water | NA | NA | 1.0 |
| Sum | NA | NA | NA | 14.9 |

In this table, each numerical value should be multiplied by the scale factor and units at the top of its column. The preferred substrate has three dielectric layers. For these added together, the total thickness is 1E-3 M. For water jets impinging on the heat transfer surface of the cold-plate, the ThRy is 1.0E-6 K per W/M̂2. This is based on measurements described in the included reference U.S. Pat. No. 5,310,440, with normalized for the cold-plate area.

The total ThRy is 14.9E-6 K per W/M̂2, equivalent 14.9 C per 100 W/cm̂2. At solar flux of 100 W/cm̂2=1E6 W/M̂2, the heat flux is about 60 W/cm̂2. Thus the front surface of the PV cell is about 9 C hotter than supply water. With inlet water cooler than 35 C, the face of the PV cell is cooler than 44 C. This temperature is very favorable for operation of relevant PV cells. This coolness enhances the photo-voltaic efficiency and reliability. This is much cooler than the prior art, which typically is 100 C to 120 C or more.

The breakdown voltage between hot wire and the ground plane ought to safely exceed the highest applied with a large safety margin. For example, this is 600 V in the NA and 1,000 V in the EU. The high voltage design is symmetrical about ground, so an extra factor of 2× may be included. Thus the dielectric ought to safely withstand more than 1,200 V in the US, and more than 2,000 V in the EU. The worst case is the 0.3 mm dielectric between the hot wires and the ground plane.

The preferred dielectric is AlN, which has dielectric strength 17E6 V/M, equivalent to 17 kV per mm. For the 0.300 mm dielectric layer between the hot wires and ground plane, the breakdown voltage is (0.6*17=5.4) kV. This is ˜5× compared to the maximum voltage of 1.0 kV in the EU, and ˜9× compared to 0.6 kV in NA. This is very ample, even with an extra factor of 2× related to the center-tapped ground-symmetric wiring for HV.

Distinctive features: This invention achieves very cool operation occurs in spite of very high concentration and very large electrical power output per receiver. This enables power generation with very low normalized capital cost. This achievement depends on several distinctive features of this invention.

Required thermal conductivity of dielectric: This ought to be greater than 15 W/MK, and more desirably greater than 60 W/MK, and highly preferably greater than 120 W/MK. The preferred embodiment is AlN at a 150 W/MK.

Required dielectric strength of dielectric: For the dielectric, is dielectric strength ought to be greater than 2E6 V/M, and more preferably greater than 6E6 V/M, and highly preferably greater than 14E6 V/M. As highly preferably embodiment is AlN with 17E6 V/M (equivalent to 17 kV per mm).

Required product of parameters of dielectric: The dielectric ought to provide sufficiently small ThRy and sufficiently large breakdown voltage. ThRy scales with thickness divided by its thermal conductivity. Breakdown voltage (BV) scales with thickness multiplied by dielectric strength. The ratio BV/ThRy cancels out the layer thickness. This scales as the product dielectric strength multiplied by thermal conductivity. This product has MKS units (V*W) per (K*M̂2). This product depends on only properties of the dielectric material.

For the dielectric, this product ought to be sufficiently large. A thermal benchmark is to provide ThRy a smaller than 10 C per 60 W/cm̂2, equivalent to 17E-6 (K per W/M̂2). A voltage benchmark is to provide breakdown voltage greater than 0.6E3 V. The ratio of these benchmarks is (0.6E3 V)/(1.7E-5 [K*M̂2] per W)=(0.35E8 [V*W]per [K*M̂2])=3.5 E7 [V*W] per [K*M̂2]. For AlN, the product of material parameters thermal conductivity times dielectric strength is (1.5E2 W/MK)*(17E6 V/M)=2.6E9 [W*V] per [K*M̂2]

For the dielectric, the product of its thermal conductivity multiplied by its breakdown voltage ought to be greater than 3.5E7, more preferably greater than 3.5E8, and highly preferable greater than 2.0E9, each multiplied by units [V*W] per [K*M̂2]. A highly preferable embodiment is 2.6E9 [V*W] per [K*M̂2] for AlN.

Required CTE: For materials [Si, AlN, Mo, Ge], their CTE values are respectively [2.6, 4.6, 5.6, 5.75] E-6 per K. This invention provides CTE match between the PV cell and the substrate, its core, its dielectric. This enables a highly reliable solder bond with small ThRy. Thermo-mechanical stress scales with the product of several factors: CTE mismatch; PV chip distance from center to the most distant corner (also called maximum “distance to neutral point” or “DNP”); inversely with thickness of the bond (solder) layer. This CTE match scales down thermo-mechanical stresses, and greatly reduces the risk of a crack in a solder bond. A solder crack would rapidly lead to acute local overheating and damage. Also, thermo-mechanical stress risks a crack in a PV cell. (Ge and Si chips are brittle.)

The CTE of the PvMcm substrate ought to be between 0 and 10E-6 per K. More preferably, between the CTE of the PV cell and the CTE of the PvMcm, the CTE mismatch should be less than 5E-6 per K. More preferably the CTE mismatch should be less tan 2.6E-6 per K. A highly preferable embodiment has PV cell made on a germanium wafer, with substrate materials Mo and AN. Thus the CTE mismatch is less than 2.15E-6 per K.

Required mechanical reinforcement: This invention provides a mechanical core-plate that is mechanically stiff and tough. This is a mechanical reinforcement than helps to prevent cracking in the dielectric, even for a relatively thin dielectric layer. This facilitates reliability and enables a thinner dielectric with smaller ThRy.

By contrast, a substrate with insufficient stiffness and toughness would risk cracks in the dielectric. This would risk degraded HV insulation between the hot wires and cold-plate, and risk water infiltration from water jets toward the core-plate. A substrate without a core would have increased risk of cracks.

Required everywhere low ThRy, without hot spots: Consider the volume between the face of each PV cell (and other locations on top of the PvMcm) and the corresponding area on the heat transfer surface.

At substantially every point in this volume, the thermal conduction vector ought to be substantially perpendicular to the surface of the PV cell.

From substantially every location the face of each PV cell, the corresponding the corresponding thermal path to the heat transfer surface {712} ought to be substantially a straight line.

This volume ought to be free of voids or other causes of poor ThRy which are wider than the chip thickness. Each layer ought to provide favorable ThRy and favorable thermal conductivity everywhere in the intersection of this region and this layer.

During power generation, this face is illuminated with approximately uniform heat flux. On this face, the temperatures ought to all be relatively cool and relatively uniform. One bench-mark is 40 C at 60 W/cm̂2, which is equivalent to 66W-6 K per W/M̂2. Another bench-mark is the table above, which calculates 15E-6 K per W/M̂2.

A substantially every location on face of each PV cell, the ThRy ought to be less than 66E-6 K per W/M̂2, and more preferably less than 33E-6 K per W/M̂2, and highly preferably less than 20E-6 W/M̂2. As described above, a high preferred embodiment provides about 15E-6 K per W/M̂2.

Counter-example: A counter-example may clarify the requirement for everywhere low ThRy. Imagine the solder layer has a void significantly wider than the thickness of the PV chip (or thickness of the small substrate of a PvScm). This causes a corresponding hot spot and extra thermal resistivity. Starting at a location on the chip face above the center this void, the corresponding heat path has a segment that goes sideways around the void, and then turns down through the solder and into the substrate, etc.

Above this void, thermal conduction vectors are substantially parallel to the PV face, rather than perpendicular. This heat path is turns, so it not a straight line. As described above, depending on various parameters, the ThRy can readily be very large, and be inconsistent with the required ThRy.

### Prior Art of Cummings and Moore (C&M)

In their pending patent application, C&M have described a solar power receiver. That is inconsistent with many features and requirements of this instant invention.

C&M dielectrics are polyimide tape and a printed circuit board (PCB). C&M metal is copper. These polyimide values are from the Dupont spec-sheet for KaptonCR. These PCB values are for type FR4.

| Material | CTE | Th. Cond'ty | Break.Str | Product |
|---|---|---|---|---|
| Units | per K | W/MK | V/M | (V * W)/(K * M\hat{ }2) |
| Scale Factor | E-6 | 1 | E-6 | E6 |
| Polyimide | 30 to 60 | 0.38 | 291 | 1.2E8 |
| PCB | 16 | 0.1 to 1.0 | 18 | (1.8 to 18)E6 |
| Copper | 17 | 400 | NA | NA |

Thermal conductivities for polyimide and PCB are each not consistent with the loosest requirement for the instant invention. Dielectric strength for polyimide and PCB are each consistent the more preferred requirement for the instant invention. The product of material parameter for polyimide is consistent with loosest requirement for the instant invention. The product for the PCB is not consistent with the loosest requirement for the instant invention.

For C&M, the thermal conductivity of the solder layer is extremely non-uniform. Through the PCB, there is an array of thermal vias. The solder layer is extremely spotty, consisting of a solder dot above each thermal via.

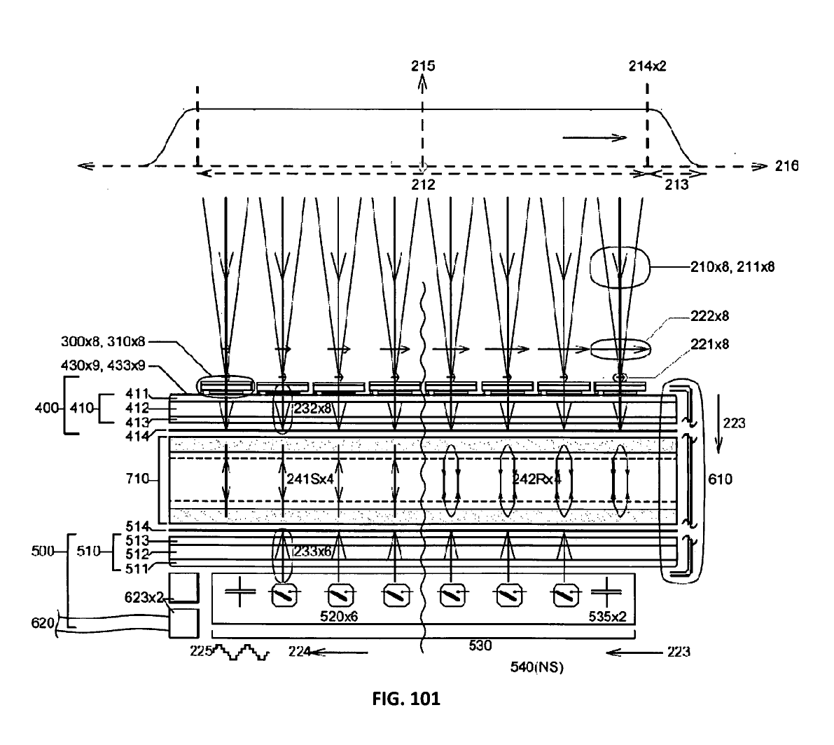

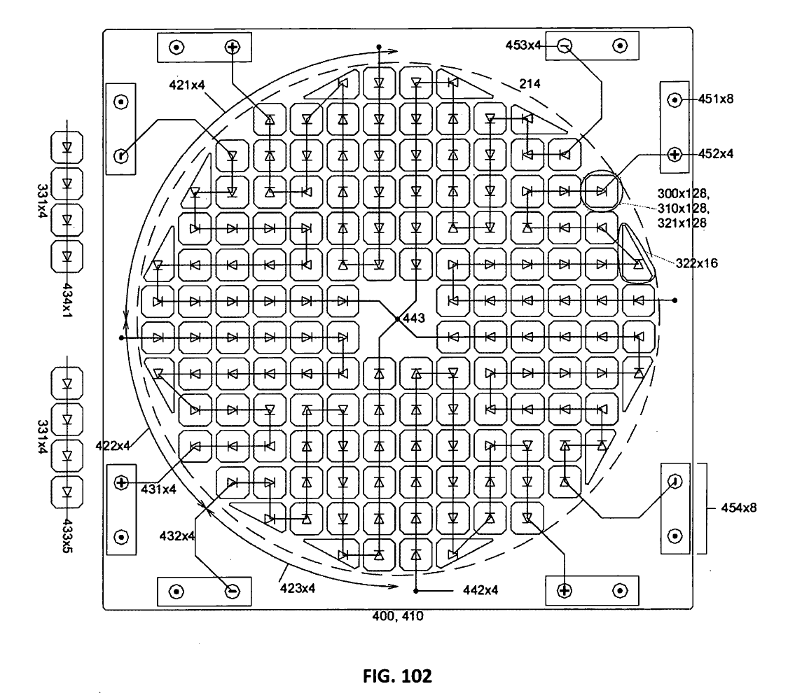

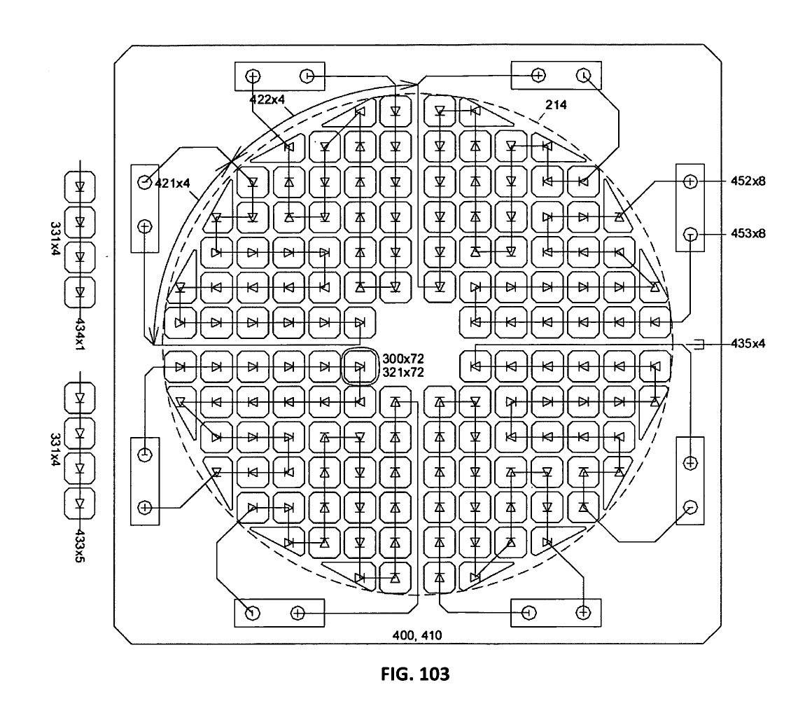

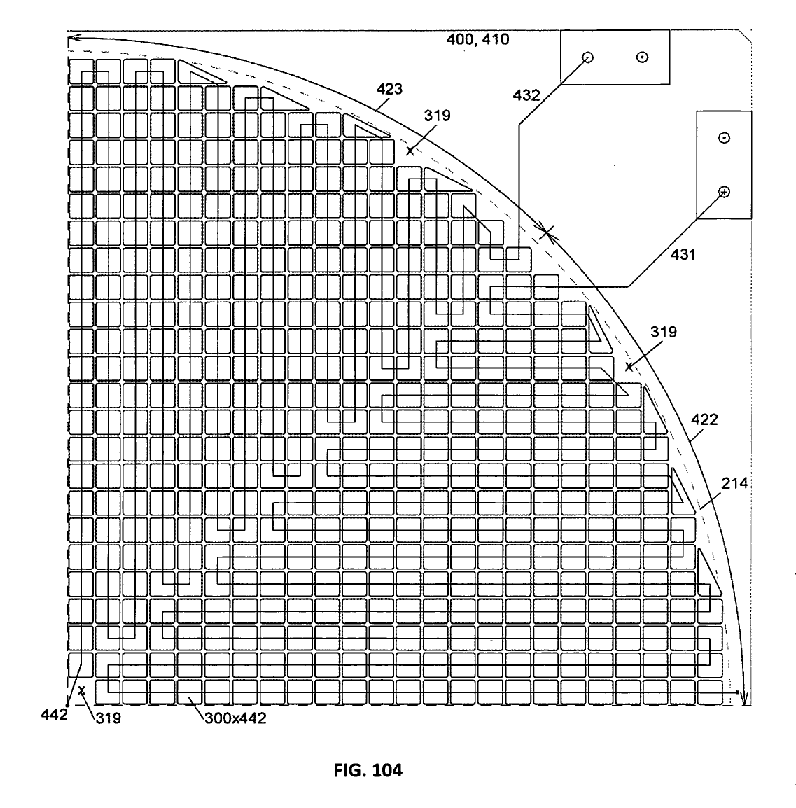

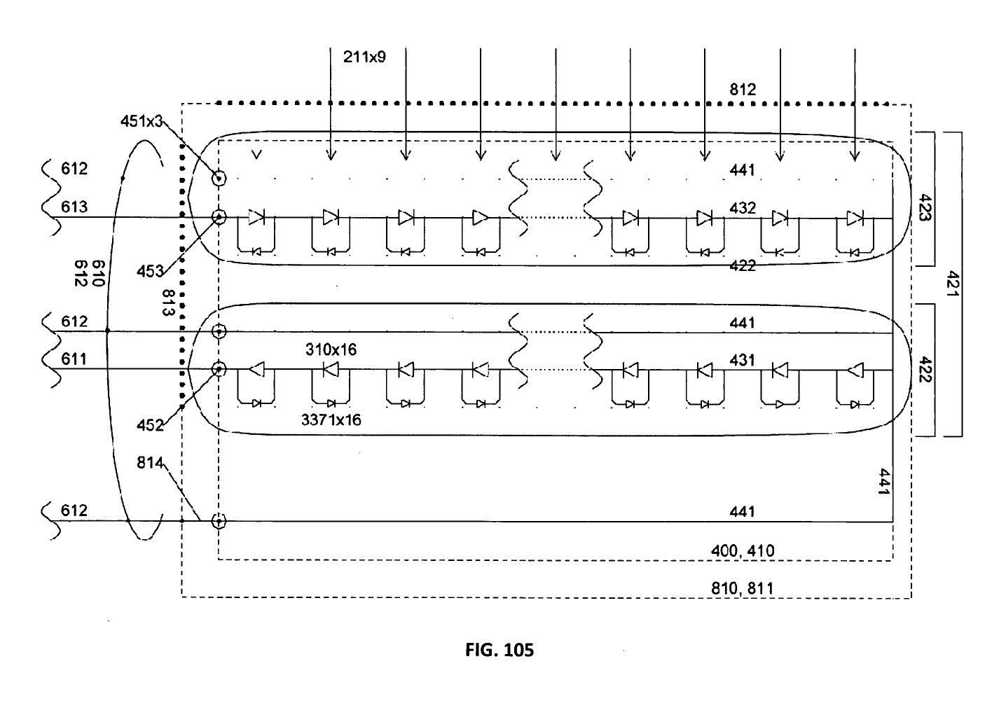

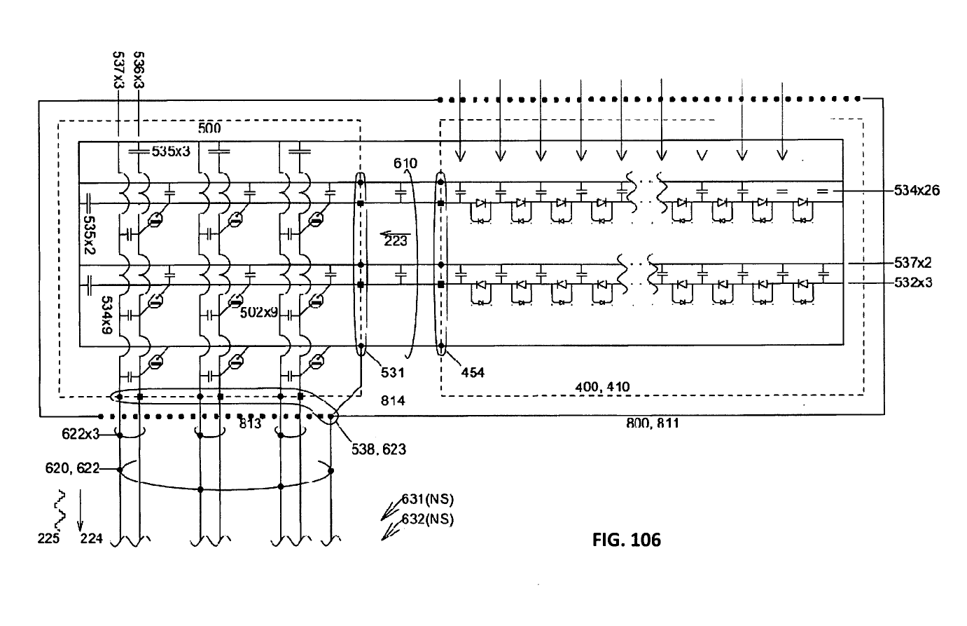

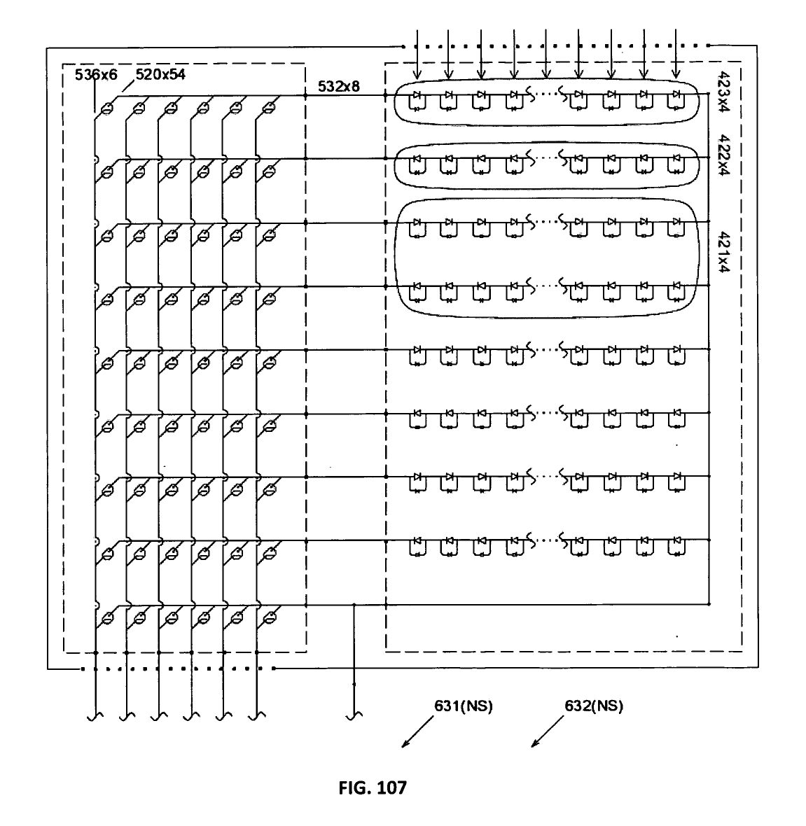

In FIG. 7B of C&M, it shows the pattern of drill holes. These define copper vias through the PCB. Careful examination and measurement of this figure indicates that each drill holes and each via has diameter about 0.5 mm diameter. These are located in a 2-dimensional array with pitch about 1.4 mm between adjacent vias. Thus the ratio of via area divided by PCB area is less than approximately (pi/4)*(0.5/1.4)̂2. Thus the area ratio is less than approximately 10%.

Between each via and the PV cell, there is a tiny solder bond. This is surrounded by a void, with diameter ˜2.8 mm. This diameter is very large compared to the PV cell thickness, both thickness 0.20 mm typically used in 2009, the 0.25 mm thickness typically used a few years ago, and the 0.50 mm typically used many years ago. Therefore the C&M design incurs considerable in-plane conduction, also called sideways thermal spreading.

C&M describes the PV cells as type A-300 from SunPower Corporation. A press release from SunPower Corp indicates its PV efficiency is about 21%, and its fabricated on a silicon wafer. The patent application date for C&M was 2007. At that date a representative thickness of silicon PV cells was roughly 0.25 mm.

SunPower and C&M both indicate the bottom of the PV cell has thin metallization. This was designed primarily to collect to collect electrical current, so is presumably quite thin. Also, thickness of this metal is presumably constrained by CTE mismatch with the PV cell, and it is necessary to avoid large thermo-mechanical stress on the PV cell. This too suggests the backside metallization was quite thin. Therefore this metallization added little to thermal conduction in the plane of the PV cell.

The design of C&M is very inconsistent with the instant invention requirement for everywhere low ThRy. Because of the pattern of via and void, at many points the thermal conduction vector in approximately parallel to the face of the PV cell, rather than perpendicular. The pattern of thermal vias and large voids adds considerable extra ThRy at locations relatively far from a thermal via. Thus temperatures on the front of the PV will have corresponding hot spots. Therefore there are island of cooler ThRy, surrounded by a rings of hotter ThRy. Also, the C&M area ratio of less than 10% is very inconsistent with the instant invention teaching this should exceed 50%.

At paragraph [208] of C&M, they describe heat power of 1 to 3 kW over a cooled area with diameter 10 to 15 cm. The center of these ranges is 1.5 kW heat over (12.5 cm)̂2, equivalent to about 10 W/cm̂2. Thus it is reasonable to infer that C&M was aimed at heat flux roughly 10 W/cm̂2, for a PV cell on a silicon wafer roughly 0.25 mm thick.

Limitation of prior art of C&M: That prior art is poorly suitable for operation with more efficient PV cells and significantly higher flux, particularly 0.2 mm thin germanium PV cells at 100 W/cm̂2.

The design of C&M provides a solder layer which is very spotty, each a large void surrounding each solder spot and via. This causes appreciable extra ThRy. That might have been tolerable at heat flux of 10 W/cm̂2, on silicon wafers roughly 0.25 mm thick.

However the C&M design is poorly suitable for power generation with: solar flux 100 W/cm̂2; very high efficiency PV cell. In 2009, PV cells with efficiency ˜40% are fabricated on germanium wafers about 0.20 mm thin.

Temperature non-uniformity scales: linearly with heat flux; inversely with thermal conductivity of wafer material for the PV cell; inversely with wafer thickness. Compared with corresponding values for C&M, the temperature difference is scaled up by a ratio (60/10)*(150/60)*(0.25/0.20)=6.0*2.5*1.25=18.8.

Under for these purposes, there is greatly increased thermal non-uniformity. Hotter ThRy degrades PV efficiency. Under sufficiently intense flux, these become quite significant. Therefore electrical output is degraded.

Within a PV cell, there are fine wires or an electro-conductive coating to harvest electrical power. These provide a parallel electrical connection between regions with unequal electrical outputs. These also enable electrical power to feed from cooler regions into hotter regions. This causes local ohmic heating in hotter regions. This causes more degraded PV efficiency and more local heating. Thus there is positive feedback. Under sufficiently intense flux, this is appreciable or severe.

These and related effects constrain the maximum feasible solar flux for the prior art of Cummings and Moore. Thus it is poorly suitable in this regime.

By contrast, the instant invention provides very easy heat transfer throughout the face of the PV cells. The instant invention prevents regions with difficult heat transfer, and thus prevents problems related to thermal non-uniformity. This readily enables operation with very high flux on germanium PV cells.

### Cold-Plate, FIG. {108}

Preamble: This section describes the cold-plate and related thermal engineering. This figure has considerable overlap with the Principal View, FIG. {101}. Thus it is sufficient to describe only concepts and components not already described there. Also this discussion applies to analogous parts of the cooling system in FIG. {109}.

Thermal Path: Highly concentrated sunlight {211} has maximum flux about 100 W/cm̂2, which illuminates each PvScm {300}. Across the area of each PV cell, about (30 to 40) W/cm̂2 is harvested as electrical power (E-pwr), and about (60 to 70) W/cm̂2 is converted to heat. However, if the E-pwr is interrupted, then 100% becomes heat. Also, on the PvMcm areas not covered by a PV cell, 100% becomes heat. There is very intense heat flux everywhere in a large area, not just at a few isolated spots. To cool this sufficiently is far beyond simple air cooling, and even beyond aggressive air cooling. Even with this intense heat flux and very large total heat power, this invention provides ample cooling, as described below.

Each PV Cell {311} is fabricated on a germanium wafer. Each PvScm {300} includes this, and optionally includes a small substrate {333}, such as AN. The PvMcm {400} has a substrate {410} with a core {412} of Mo. On each face, there is a dielectric {411}, {413}, preferably AlN. This substrate forms the outer wall {711} of the cold-plate {710}.

Heat conducts {232} successively: from the PvScm {300}, through a local bond {338} into the substrate {410}; through this to its inner surface {712}, where heat transfers into the coolant fluid {241}, {242}.

Coolant: The preferred coolant is water. Optionally this includes antifreeze, such as ethylene glycol or propylene glycol, includes an anti-corrosion additive, such as benzotriazole (BTA), and includes a buffering agent. During single-phase cooling, the coolant fluid is a liquid {240}, and does not evaporate or condense. Water has excellent thermal parameters. Less preferred embodiments include various hydrocarbon fluids, silicone fluids or even refrigerant fluids. These are commercially available for heat transfer.

Solder and temperature sequence: From the PvScm {400} to the substrate {510} of the PvMcm {500}, there is a local bond {338}. This provides both good electrical conductivity and good thermal conductivity. In the preferred embodiment, this bond is solder. In the assembly sequence, process temperatures should decrease monotonically. Therefore this solder is selected to fulfill this goal.

Solder: There are many lead-free solders, and these can be applied at various temperatures. For the solder layer {338} between the PV cell and the PvMcm, one suitable solder example is pure tin (Sn) with melting point 232 C. More generally, a wide range of solders are provided commercially by Kester Solder, by Indium Corp, by Arconium Corp. and others. From these menus the solder(s) should be selected to correspond to the assembly sequence for this solar receiver. In particular, earlier processes should use higher temperatures, and later processes should use lower temperatures. Also, the solder layer(s) should be free of any oxide surface layer, to avoid corresponding interface thermal resistance. Further details are provides in U.S. Pat. No. 4,685,606, by Zingher and Gruber, and titled “Oxide-free extruded thermal joints”

Internal structure and function of the cold-plate: Inside the cold-plate there are is a dual internal manifold and two nozzle-sheets. Into the cold-plate {710}, cool supply liquid {241S} flows in, through an internal hydraulic manifold {713S}, though a hierarchy of internal conduits {714S} to a nozzle sheet {721}.

The incorporated reference U.S. Pat. No. 5,310,440 describes in detail the nozzle-sheet, plus its nozzle-holes, its spacers, and other features. That incorporated reference provides detailed figures and dimensions. All of those are hereby incorporated by reference.

The following is a handy summary, but actual details are to be found in the incorporated reference. The nozzle-sheet is a metal sheet with features: very many tiny nozzle-holes that penetrate this sheet; very many tiny spacers that protrude from this sheet; a smaller number of relatively large return holes that penetrate this sheet. For example, the nozzle sheet is a thin stainless steel, chemically machined features. The spacers define a thin gap, between the nozzle-sheet to the heat transfer surface. Each nozzle hole has a very small diameter. Each return hole is considerably larger. The nozzle-hole locations correspond to the expected map of heat into the heat transfer surface.

From the supply conduits, supply fluid squirts through each nozzle, and emerges as a small jet {722}. This impinges onto the heat transfer surface {712} where it very efficient absorbs heat. This creates return fluid {242R} that is warm return liquid {243} for single-phase cooling, or return vapor {244} for two-phase cooling. In either case, the return fluid {241} has more internal energy per unit mass compared to the supply liquid {241}.

The return fluid {242} flows back, through another hierarchy of internal conduits {714R}, through the internal manifold {713R}, through the outlet {715R}, and thus out of the cold-plate {710}. The supply and return conduits are in various planes. Nevertheless, for graphical clarity in FIG. {108}, both are illustrated in the plane of this figure.

The cold-plate consists of several layers. A mask or mold can be used to fabricate each layer. This enables very efficient fabrication. Thus the cold-plate {710} is simple and economical to manufacture. This may be described as a printed circuit for fluid flow and heat transfer.

Coolant flow is extremely topologically parallel. Each fluid stream-line flows close to the outer wall for at most a very short distance, and then flows perpendicularly away from wall. Each fluid stream-line removes heat from at most a small region under one PvScm. Heat from one PvScm does not pre-heat the flow for another PvScm. This prevents formation of a thick thermal boundary layer which degrades heat transfer into the liquid. This prevents “fully developed flow”.

The cold-plate, including the PvMcm, rigorously encloses the supply liquid {241} and return fluid {242}, except for the inlet and outlet {714 S, R}. This helps to prevent leaks.

On the bottom of the cold-plate, it colds the SwMcm {500} and its power switches {520}. This is analogous to cooling for the PvMcm {400} and its PvScm's {300}. Therefore the dual internal manifold provides top conduits and bottom conduits. There is a nozzle-sheet on the top, and another on the bottom. The inlet {715S} and outlet {715R} of the cold-plate {500} are both located on the mid-plane and serve both top and bottom.

However the SwMcm and its switches provide far less total heat and maximum heat density, and this heat is quite non-uniform, compared to the PvMcm and PvScm's. Therefore the bottom nozzle-sheet has far fewer nozzle-holes and return-holes, and their locations correspond to the non-uniform heat distribution.

Incorporation by reference: U.S. Pat. Nos. 5,265,670, and 5,310,440 provide figures and descriptions of internal structures and functions of a cold-plate, including: manifold; nozzle sheet; fluid flow hydrodynamics and heat transfer; design and methods for manufacturing. These patents are hereby incorporated by reference, and those descriptions, figures, dimensions and details generally apply to the preferred embodiment for the instant invention. However, the instant invention differs slightly, by providing cooling on top and on bottom, as described above.

Illuminated disk and reflectors: It is counter-productive for concentrated sunlight to be absorbed by PvMcm {500} in areas other than a PV Cell {310} on a PvScm {300}. This increases the heat load, but does NOT generate more E-pwr. This is minimized by the following.

First, the upstream optical system substantially uniformly illuminates a disk. In FIGS. {102}-{104}, this disk is marked by its circular limit {214}. This disk is geometrically approximated by the array of PvScm's {300}. This array is densely filled by PV cells, with relatively little intervening area.

Second, there is a reflective shield {761} just above the outer area of the PvMcm {300}. This is shown in FIG. {108}. One embodiment is a conical reflector close to the plane formed by PV Cells. This casts a shadow with a sharp edge, shown as {214} in FIGS. {102}-{104}. The shield reflects most sunlight beyond this edge. Even so, this will absorb some optical power. Therefore this shield connected to and cooled by the cold-plate.

Third, the topmost layer of the substrate of the PvMcm reflects most sunlight. For example, this may be a distinct coating, which is white and dielectric. This must NOT be electro-conductive or electro-resistive, even in the high resistance (leakage current) range. Alternatively, this may be the top-most dielectric layer. This optically shields printed power wires areas and other areas that would otherwise be exposed and absorb sunlight. However this coating is absent upon metal pads for electrical connections or solder bonding.

### Preamble: Cooling System External to Cold-Plate, FIG. {109}

FIG. {109} overlaps considerably with the Principal View and Cold-plate, FIGS. {106} and {108}. For items and tags shown and described for FIG. {101} and {108}, they also apply to FIG. {109}, even though they are explicitly not tagged or described here. Instead, it is sufficient to tag and describe only items and components that are distinct for FIG. {109}. As shown in FIG. {109), and explained in a later section, the preferred cooling system provides two modes for cooling.

FIG. {109} has a non-uniform scale. The cold-plate {710} is shown greatly exaggerated in height, and also exaggerated in width. The external heat exchanger {740} and air-cooling hardware {751} thru {754}, are all shown greatly reduced in both height and width. The tubes {732} are shown greatly reduced in height/length.

One-phase power-driven cooling mode: This is the preferred mode for a sufficiently large system that can justify more sophisticated cooling, more frequent maintenance, where external power is steadily available. This cooling is activated with and liquid pumps {732} plus motors {754} with fans {753}. This mode enables: better air cooling; better liquid flow; better thermal uniformity in the cold-plate; cooler operating temperature and/or greater power density for the PV cells. Preferably there are two fans and two pumps, each with its own motor. This redundancy improves reliability against some failures.

Two-phase power-independent cooling mode: This mode uses thermo-siphon cooling and thermo-buoyant air cooling. For each, flow and cooling are activated by gravity, a density difference, and a height difference. (See below for more description.) Each is independent of external power, and thus is NOT vulnerable to failure of external power. This is useful for back-up cooling when external power fails.

This mode is useful when or where external power is not steadily available or maintenance is less available. Cooling operation in this mode relatively simple, if this is properly engineered, constructed and installed.

This mode can provide very adequate cooling for relatively small or medium embodiments. This mode can be used for normal cooling, without the capital cost for fans and pumps. Cooling operation is relatively simple, if this cooling embodiment is properly engineered, constructed and installed. Here it can provide a good balance between reliability, cost and cooling performance.

This mode incurs disadvantages, particularly for a large embodiment. This provides relatively moderate performance for air cooling and/or requires relatively large air cooling hardware. For successively larger systems, there is successively more vulnerable to non-uniform flow distribution and hot spots in the cold-plate. This is more vulnerable to chemical engineering in its design, materials, manufacturing, and installation.

Plural mode cooling: For a large system, the preferred embodiment provides both of the above modes, and changes between them depending on the availability of external power. Another section (see below) describes the cooling dynamic during transition between these modes. This contrasts sharply with the prior art, where externally-pumped one-phase cooling and thermo-siphon two-phase cooling were mutually exclusive.

Regimes: The preferred embodiment depends on the maximum system power. The boundary is not sharp, but is roughly between about 18 to 36 kW of heat, corresponding to about 27 to 54 kW output power.

Flexibility: In FIG. {109}, near the cold-plate {710}, fluid coolant {240S, R} flows in and out through flexible metal bellows {731S, R} and to/from adjacent tubes {732S, R}. The flexible bellows permit bending and prevent cracks in the cold-plate or tubes. The bellows are preferably as close as feasible to the cold-plate. Nevertheless for graphic reasons, each bellows is shown on the far side of a bend in a tube.

### Single-Phase Power-Driven Cooling, FIG. {109}

Hydraulic pump: Returning liquid coolant {241} flows through at least one liquid pump {733}. This is magnetically driven by an electro-magnetic stator outside the tube. The stator provides a rotating magnetic field which penetrates the tube. Fully inside the tube, this drives a rotor/impeller. This avoids rotary seals and possible leaks.

The pump type is selected to enable flow through the pump, even if the pump is stopped. For example, this is an axial flow pump (also called a propeller pump) or a centrifugal pump. This excludes various displacement pumps.

For a sufficiently large system, the preferred embodiment includes a second hydraulic pump {733} with a separate power supply. If either pump is operating, it will provide ample flow for ample cooling.

External heat exchanger: After the cold-plate {710} and return tube {732R}, the warm return liquid {242} flows to an external heat exchanger {740}. Thus heat is transferred to external air {752} driven by a fan {753} and motor {754}. This uses the extensive prior art of heat exchangers from liquid to air.

This heat exchanger preferably has inside area that is much larger than the inside of the cold-plate. This scales down the heat density, and thus facilitates heat transfer. Optionally, the condenser has internal thermal enhancements {743}. These may include internal fins {744} and/or small internal fins and grooves {724}, and/or an internal manifold {745}. These reduce thermal resistance due to thermal boundary layers, and facilitate thermal transfer from all warm return fluid.

Power-driven air cooling: The outside of the external heat exchanger {740} has an array of many large but slender metal air fins {741}. The external heat exchanger {740} is much larger than drawn FIG. {109}. A motor {754} turns a large air fan {753} that provides large air flow {751} over the air fins {741}. The total area of the air fins preferably is very much larger than illuminated area of the PvMcm. This decreases the thermal density, and counteracts the poor thermal parameters of air.

Preferably the cooling system includes at least two fan and motor sets. Either set provides ample air flow for full cooling operation. This provides redundancy against fan and motor failure.

### Two-Phase Power-Independent Cooling with Cold-Plate, FIGS. {109} with {106}

Thermo-siphon loop cooling: Supply liquid {241S} flows in through a supply inlet {715S}, through an internal manifold {713S}, through internal conduits {714S}, through a nozzle-sheet {721} with nozzle-holes. Here, supply liquid jets {722S} impinge onto the heat-transfer surface {712} on the cold-plate {710}. More descriptions and figures are provided by the incorporated references.

During thermo-siphon circulation, on the heat transfer surface {712}, these liquid jets {722S} evaporate and form return vapor {244R}. This expands strongly and flows away, through internal conduits {714R} of the internal manifold {713R}, through the return outlet {715R}, from the cold-plate {710}, through the return bellows {731R} and return tube {732R}.

Eventually return vapor {244R} reaches the condenser {746} in the external heat exchanger {740}, where it condenses and thus releases heat. The condenser may include internal thermal enhancements {743}, such as described above. Thus heat conducts from condenser {740}, into external air fins {741}, into external air {751}, which is blown away.

This condensation forms supply liquid {241S}. In a thermo-siphon, the condenser {746} is higher than the cold-plate {710}. Therefore, liquid coolant {241} flows back, through a supply tube {732S}, through supply bellows {731R}, and again into the cold-plate {710}. Then the cycle repeats.

The thermo-siphon effect activates fluid flow. The liquid return fluid {242} is much denser than vapor return fluid {243}. The condenser {746} in the external heat exchanger {740} is considerably higher than the cold-plate {710}. This height difference, density difference, and gravity acceleration {260} together cause a hydrostatic pressure difference which activates circulation of the supply liquid {241} and return vapor {244}.

Evaporation and condensation strongly transfer heat. Thus two-phase cooling uses a considerably small mass-flow rate than one-phase cooling.

The supply liquid {241} and return vapor {243} flow in separate tubes, which facilitates flow. Thus a loop thermo-siphon can transfer many kilo-watts of heat. Furthermore, this loop topology is compatible with one-phase cooling, as described above. This contrasts with supply liquid and return vapor flowing in opposite directions inside the same tube.

Thermo-buoyant air cooling: The air fins also enable thermo-buoyant air cooling (“natural convection”). This is activated by a temperature difference, height difference, gravity and properties of air. Compared to power-driven air cooling, this requires larger air cooling fins. Also, a chimney or equivalent is a preferred option.

Depending on the embodiment, thermo-buoyant air cooling may provide less cooling than fan-driven air cooling. Even so, this can sustain considerable power generation.

### Graceful Shutdown

The cooling system may occasionally experience failure beyond the power failure and mode-change describe above. The preferred embodiment provides two shutter mechanisms to rapidly prevent concentrated sunlight on the PvMcm. One shutter embodiment interrupts the tracker motion, and thus miss-aims the optical sub-system. Other shutter embodiments use an optical reflector or optical absorber.

Interrupt tracker: This is a very reliable mechanism for graceful shutdown. The optical system provides high concentration. Therefore it accepts sunlight within a narrow cone around the optical axis. Therefore, the opto-mechanical system and tracker aim at the sun within a narrow acceptance cone. This and daily rotation provide a different way to prevent concentrated sunlight after a failure.

For example, the angular diameter of the optical acceptance cone is about 1.5 times the angular diameter of the sun. Thus optical miss-alignment by 1.5 solar diameters will change acceptance from maximum to nearly zero.

The angular diameter of the sun is about 1 degree. The earth's daily rotation is 360 degrees in 24 hours. Therefore sun appears to rotate from east to west by one solar diameter in a time interval:

(24 hours)*(1 degree)/(360 degrees)=(4 minutes).

Suppose the sun and optical system are aligned at the moment that power fails and the tracker stops. The sun will move entirely outside the optical acceptance cone in a time interval:

(4 minutes)*(0.5+1.5/2)=(4 minutes)*(1.25)=5 minutes=3E2 sec

In a preferred embodiment, there is enough stored coolant and evaporative cooling capacity to provide temporary cooling during at least this interval. Even so, a faster mechanism is provided by the shutter described below.

In a variation, the tracker includes means for rapid motion, as well as slow steady daily motion. This reduces the interval until the sun is blocked. However this requires means to operate even when external power fails. This is provides by auxiliary energy storage, such as a battery or spring.

Shutter and interlock: This enables a graceful shut-down. A shutter is a means to change the optical path for sunlight, and thus prevent concentrated sunlight on the PvMcm. This shutter is interlocked with a signal correlated with cooling failure, or other abnormalities. This signal may be based on sensors concerning: external power; pump action; coolant flow or pressure or weight; temperature related to PvMcm or PvScm or PV cells; fan action. Also this signal may be based on leading or early indicators which are correlated with future or imminent problems. These included: warning of problems with external power; indicators of wear leading toward failure in pumps; rapid measurement of electrical abnormalities. In many cases these leading or early indicators provide lead time more than the brief latency for a shutter to prevent concentrated sunlight. This interlock enables a graceful shutdown.

One shutter embodiment acts by interrupting the tracker, as described above. Various optical elements can serve as a shutter. In addition to an optical absorber-shutter, there are many more shutter types. These include: shutter-tracker, shutter-mirror, shutter-reflector, shutter-absorber, shutter-prism, shutter-optical scatter, shutter-prism and more. This can use various optical elements which can change the optical path. Various changes can be used: change may use: reflection, deflection, scattering, focusing and defocusing, absorbing.

Many shutter embodiments involve a movable optical element. Its position is controlled by an actuator with a stored-energy device. In one position, the optical element is outside the optical path. In the other position, the optical element is inside the optical path. This changes the optical path, and thus prevents concentrated sunlight on the PvMcm

The stored energy is high for normal position, and low for the abnormal position. Initially, the actuator forces the optical element and stored-energy device are forced into the normal position. Thereafter a moderate current maintains this position. When current is interrupted or stopped, the optical element moves to the abnormal position. Thus there is considerable asymmetry between opening and closing the shutter.

Examples include a mirror, a diffuse reflector, or an optical absorber, plus an electro-magnet with ferromagnetic latch-plate and a spring. Thus, a mirror-shutter or diffuse reflector-shutter can reflect sunlight, and thus block the normal optical path. In another version, the optical element is always in the optical path, but can enable or deflect sunlight on normal optical path. Other shutter embodiments are a relay-mirror or a lens. This can change its direction, and thus disable or enable the normal optical path.

Other embodiments depend on a property of the coolant liquid versus vapor, such as the optical index, pressure or its weight. An embodiment is a box or prism with transparent walls, filled with transparent pieces and voids. A transparent coolant liquid, such as water, flows through these voids. The liquid coolant and these transparent pieces have similar refractive indexes, but air or vapor has a very different optical index. When the voids are filled with liquid coolant liquid, then this box or prism is optically transparent. When the voids are filled with air or vapor, then this scatters light.

Thermal engineering for shutter: The shutter is subject to solar heating. The shutter preferably includes passive air fins or other cooling. Thus its temperature will approach a steady state, rather than rising indefinitely. Also the shutter preferable has significant thermal mass. This will decrease rate of temperature rise.

A reflective shutter minimizes solar heating, and thus eases thermal engineering.

An absorptive optical element blocks sunlight by absorption. This maximizes solar heating and requires corresponding maximum thermal engineering. For example, this provides large air fins, considerable thermal mass, and a durable material with high thermal conductivity. An example is a thick plate of iron, on an iron axle which conducts to large air fins. This axle enables both movement and cooling. This iron and axle are coated with zinc prevent corrosion.

Shutter reliability: It is important for the shutter to provide excellent reliability during many years. The preferred embodiment includes at least two shutters, with different and independent mechanisms. The shutter should be exercised frequently, such as near each sun-set and each sun-rise. The shutter should be inspected and maintained at appropriate intervals, such as once per month. More abstractly, the shutter and its operation are designed to extremely reliable in spite of diverse ambient perturbations. Beyond solar heating, these may include: corrosion, adhesion, rain, dust, salt, extremely hot or extremely cold weather, plants, animals, etc.

### Transitional Cooling

Requirements: A shutdown or transition is “graceful” if it occurs without damage, especially due to overheating. This system provides a transition from one-phase externally-driven cooling to two-phase power-independent cooling. This section teaches how features and functions for a graceful transition, in spite of several complications.

One complication is a major accident during bright sunlight. This might cause a large leak or rupture in the cooling system, and loss of most coolant fluid. (This resembles the “loss of cooling accident” or “LOCA”, which is known in nuclear reactor engineering) However, highly concentrated sunlight may continue on the PvScm's and PvMcm. This section describes how this invention provides sufficient cooling for a graceful transition.

Another section describes how highly concentrated sunlight will be prevented by stopping the tracker, or stopped by a reflective shutter, etc. These transitions occur respectively in less than in 300 sec and 5 sec. This invention provides sufficient cooling during these intervals, until concentrated sunlight is stopped.

Another complication is “thermal over-shoot” during just before the start of boiling. In the cold-plate just before evaporation starts (boiling), the local temperature momentarily rises above the boiling temperature (“thermal over-shoot”). Then evaporation starts, steam expands strongly, the temperature drops to almost the boiling temperature. This section describes how this invention minimizes thermal overshoot. (These features partly resemble the geo-thermal geyser “Old Faithful” in Yellow Park, USA).

Other transitions: These features and functions provide similar graceful transitions in other cases. For a large embodiment, the preferred embodiment of FIG. {109} normally uses single-phase power-driven cooling. External power might stop abruptly. This invention provides a graceful transition to two-phase thermo-siphon cooling.

In some embodiment, particular for medium or small embodiments, normal cooling is a two-phase thermo-siphon. A similar transition occurs when this embodiment starts: from zero flow; to a steady state thermo-siphon.

Representative temperatures and safety margin: Under normal operating conditions, the ambient temperature is below 45 C, and PV Cell temperature is below 85 C. A PV cell can operate indefinitely at 120 C, but with reduced efficiency. A prudent ceiling is ˜250 C, which is approximately the solder melting point. The PV Cells tolerate this briefly during assembly of the PvMcm. A PV cell might briefly tolerate ˜300 C. Irreversible damage probably will occur above ˜325 C.

These temperatures have the following significance. During normal operation, the temperature difference is about 85−45=40 C. During a few minutes, the PV cells can tolerate 250−45=205 C.

The ratio of these temperature differences is 205/40=5.1. This is a large safety margin. Thus PV cells can briefly tolerate cooling that is 5.1 fold weaker than normal. Thus it is relatively easy to provide transitional cooling sufficient to prevent short-term damage.

Transitional cooling by evaporation: The preferred embodiment uses water as coolant. This has very large “heat of vaporization”. Thus a small amount of coolant is sufficient during a transition. Here is an estimate of this amount:

For pure water, the heat of evaporation is 2.4E9 J/M̂3. At heat flux (100 W/cm̂2) onto the PvMcm, the evaporation rate is equivalent to:

(1.0E6 W/M̂2)/(2.4E9 J/M̂3)=(0.44E-3 M/S)=(0.44 mm/sec)

Thus a small thickness (depth) of water is sufficient for transitional cooling:

(0.44E-3 M/S)*(0.5E1 S)=0.22E-2 M=0.22 cm for shutter to act

(0.44E-3 M/S)*(3.0E2 S)=13E-2 M=13 cm for interrupted tracker to act

Hydraulic Design: There a hydraulic accumulator {734} upstream of the inlet to the cold-plate. The accumulator {734}, supply tube {732S}, and cold-plate {710} are designed to very reliably prevent leaks or ruptures, even under abnormal conditions. These are designed to limit the flow rate during passive flow (without pumping), even with a large rupture at the cold-plate outflow. These are designed so draining the hydraulic accumulator takes more than 5 minutes. These are designed so sufficient water (see above) remains, even after prolonged draining.

Hydraulic accumulator: This {734} stores some liquid coolant and stores some corresponding energy to drive passive flow. One example is a reservoir at higher altitude than the cold-plate. A second example is a closed reservoir with enclosed compressed gas that can drive flow. A third example has a backup battery that can feed a small pump and drive flow. A fourth example has an elastic spring and piston that can drive flow. The prior art provides many additional suitable types.

Transition dynamics: Suppose there is concentrated sunlight and pumped flow. Then the pump {734} stops, flow decrease greatly, and PvMcm temperature rises. Water temperature rises past 100 Celsius, and then evaporation and vapor pressure rapidly increase.

During evaporation and condensation, the vapor pressure curve describes the relation between temperature (Temp. in C) and absolute vapor pressure (V.P. in Bars). For pure water, here are representative values.

| 60 | 80 | 100 | 120 | 130 | 140 | 160 | 180 | 200 | 300 | Temp. |
|---|---|---|---|---|---|---|---|---|---|---|
| 0.20 | 0.47 | 1.01 | 2.0 | 2.7 | 3.6 | 6.2 | 10.0 | 15.6 | 67 | V.P. |

Transition following a large rupture: Suppose the return tube {732R} is completely ruptured just beyond the return outlet {715R} of the cold-plate {710}. Adjacent to the inner surface {712} of the substrate {420}, coolant liquid evaporates. Vapor flows outward: through the manifold {713}, through the return outlet {715R}, through the rupture, into the ambient air. The flow cross-section is relatively large. Therefore inertial drag and viscous drag are small, and pressure inside the cold-plate {710} is mildly above ambient pressure. Because of the vapor pressure curve, the temperature inside the cold-plate {710} is mildly hotter than 100 C. Also, because of the mild over-pressure, there will be mild back-pressure against in-flow from the hydraulic accumulator. The hydraulic accumulator will briefly sustain this flow, and thus sustain this temperature. Soon the shutter and daily rotation stop the concentrated sunlight. Thus there is graceful shut-down.

Transition inside a closed system: Suppose the external power and pump stop. Suppose the hydraulic sub-system is NOT ruptured, and concentrated sunlight continues. Inside the cold-plate {710}, there is a nozzle-sheet {721}. The incorporated references provide a detailed description. This has supply nozzles with small total area, and return holes with much larger total area. Because of this asymmetry, it is easier for vapor to flow downstream to the return outlet {715R}, rather than upstream to the supply inlet {715S}.

The PvMcm temperature rises, liquid water evaporates to vapor, and the internal pressure increases. Vapor flows outward, and pushes liquid ahead: through return conduits {714R} of the internal manifold {713}, through the return outlet {715R}, through the return tube {732}, through the external heat exchanger and condenser {740}. Next, vapor flows back through the supply tube {7325}, back to the hydraulic accumulator {734}. Thus vapor pressure flows around the hydraulic loop, and is balanced on both sides of the accumulator {734}.

During this transition, the maximum pressure occurs when vapor begins to push liquid coolant around the loop. In a representative case, this includes less than 1.0 Bar to overcome hydrostatic pressure, plus less than 0.5 Bar to nucleate a bubble, plus 1.0 Bar for ambient pressure. Thus the maximum absolute pressure is less than 2.5 Bar. For pure water, its vapor-pressure curve implies the maximum temperature is cooler than 130 C.

The preferred coolant also includes additives, such as anti-freeze and corrosion inhibitor. Their effect is described by Raoult's law. Thus the maximum temperature is cooler than 140 C. Inside the condenser, vapor condenses and heat is removed. This leads to a thermo-siphon steady state, with balance between evaporation inside the cold-plate and condensation inside the condenser. Thus steady-state temperature is slightly hotter than 100 C.

Thus there is a graceful transition: from one-phase cooling with pumping; to thermo-siphon two-phase cooling without pumping. During this transition, the maximum temperature (thermal over-shoot) is less than 140 C. Thus over-heating and damage are avoided.

For a thermo-siphon at steady state, the PV Cell temperature is a little hotter than 100 C. A thermo-siphon has relatively small mass flow rate, because of the large heat of vaporization. Thermo-siphon cooling does not need a pump, and does not depend on external power. This enables less capital cost. This is particularly favorable for an embodiment with small to medium granularity (electrical output power per system).

By contrast, large granularity economically justifies a pump. This enables much larger mass flow, one-phase cooling. This provides steady-state temperature significantly cooler than 100 C. This lower temperature enables more efficient PV cells.

### Reliability Block Diagram, FIG. {110}

To rigorously prevent severe overheating and damage to the PV Cells, PvScm's and PvMcm, the preferred embodiment provides many levels of cooling and protection: one-phase power-drive cooling; two phase power-independent cooling; shutter; tracker shut-down. These together very reliably guarantee graceful shutdown and thus guarantee against overheating and damage. These incur added capital cost. This is relatively moderate and worthwhile compared to a large embodiment.

Diagram Style: This block diagram summarizes the redundancy of the cooling system. Each small rectangle represents the status of a component, and is labeled with the name of this component. The components in the 1st column provide steady full function. The components in the 2nd column provide steady backup that prevent acute overheating of the PvMcm. The components in the 4th column provide transitional functions, and provide graceful shutdown.

Each large chamfered box represents the effect, caused by one of more several inputs. This box is labeled with name of the effect, and by the Boolean logical operation (AND, OR, NOT, XOR) which combines its inputs.

Each of these items represents a graph of magnitude versus time: air flow for {7711}, {7712}, {7722}, {7741}; liquid flow for {7713}, {7714}, {7723}; thermal resistance {7742}, {7751}, {7761}; temperature {7771}; liquid flow {7744}, {7745}, {7752}; thermal resistance {7762}; binary variable {7746}, {7747}, {7748}, {7753}; solar flux {7763}; temperature {7772}.

Power-driven cooling {7771}: The [Fan & Motor 1] {7711} OR [Fan & Motor 2] {7712} provide [Steady Large Air Flow] {7722} and thus [Steady Air Flow] {7741}. The [Pump & Motor 1] {7713} OR [Pump & Motor 2] {7714} provide [Steady Large Liquid Flow] {7723}and thus [Steady Heat Transfer] {7733} inside the Cold Hat {710} (not shown).

Normal cooling: The [Steady Air Flow] {7732} AND [Steady Heat Transfer] {7733} together provide [Steady Cooling] {7751} and hence the [PvMcm Temperature] {7761} is quite cool.

Thermo-buoyant air flow {7721}: This provides small [Steady Air Flow] {7731}. This AND [Steady Heat Transfer] {7733} together provides enough [Steady Cooling] {7741} so the [PvMcm Temperature] {7751} becomes warm but tolerable during a long interval. This is important during failure of both fan and motor sets, such as failure of input electrical power.

Two-phase cooling {7772}: This operates independently of electrical power. This {7772} may be used steadily or briefly, depending on the embodiment. After [Initiation] {7724}, then is a loop of steady processes. These include: [Evaporation] {7734} in the Cold Hat; flow of [Supply Vapor] {7735}; [Condensation] {7716} in the external heat exchanger; flow of [Return Liquid Flow] {7715}; and again. This provides flow and transfers heat from the Cold Hat.

For a system whose total power is not too large (such as below about 32 kW), then [Phase change cooling] {7712} can provide very good cooling, as per FIG. {110} which is independent of external power. One embodiment uses this as normal cooling.

Another embodiment normally uses pumped liquid cooling, as per FIG. {109}. However, if there is failure of [Steady Large Liquid Flow] {7724}, then [Initiation] {7724} occurs, and this changes to [Phase change cooling] {7772}.

Graceful shutdown {7773}: This is triggered by loss of electrical power. When both pumps fail, then [Accumulator 1] {7725} OR [Accumulator 2] {7726} provide [Brief Liquid Flow] {7736}. This AND [Steady Air Flow] {7732} together provide at [Brief Cooling] {7742}. This provides ample time to achieve [Graceful Shutdown] {7752} using the [Shutter 1,2] {7743} {7744}.

When the [Electromagnet 1] {7738} looses power, it releases the preloaded [Spring 1] {7742}. In a short time, this moves the [Shutter 1] {7753}, and thus causes [Prevent concentrated sunlight] {7753}. Also [Electromagnet 2] {7728}, [Preloaded Spring 2] [7738] a [Shutter 2] {7744} operate similarly.

[Prevent Concentrated Sunlight] [7753] AND [Brief Cooling] {7742} together achieve a [Graceful Shutdown] {7762}. Thus the [PvMcm Temperature] {7761} is always cool and sunlight is securely prevented.

Electrical power is required to reset the following: [Pump and Motor] {7713}, {7714}; [Fan and Motor] {7712}, {7713}; [Accumulators] {7736}, {7737}; [Tracker] {7739≡these must be fully restored BEFORE resetting the [Electromagnet 1,2] & [Spring 1,2] & [Shutter 1,2] {7738} & {7742} & {7753}.

Shut-down using Tracker {7754}: The [Daily rotation] {7729} is normally matched by the [Tracker] {7739}. The [Tracker] {7739} stops when external electrical power fails. After a few minutes, the misalignment is so large it provides [Slow Shut Down] {7754}. If the Accumulators are large enough to maintain flow during this transition, then this is another [Graceful shutdown] {7752}. Further aspects of cooling

Features for uniform cooling: One-phase and two-phase cooling both are easier for smaller granularity. With larger granularity, it is more challenging to provide flow and cooling which are sufficiently uniform and sufficiently intense. This is achieved by several features.

Inside the cold-plate {710} there is an internal manifold { 173 } and a nozzle sheet {721}. This manifold has a hierarchy of conduits {714S, R} that provide highly parallel flow. These conduits have total cross section that is uniform and sufficient, and these are internally streamlined. Therefore the inertial hydrodynamic drag is quite small. Therefore this internal manifold enables abundant flow density with very modest differential pressure.

A second feature is the nozzle sheet {721}. This has small holes for supply liquid, plus large holes for return fluid. During coolant fluid flow at a large mass rate with single-phase heat transfer, the supply holes provide pressure drops that are large enough to balance stream-line speeds. During coolant fluid flow at a small mass-flow rate with two-phase heat transfer, there is a large volumetric flow of return vapor. At the return holes, this provides sufficient pressure drop to balance stream-line speeds. Thus for both modes, this provides sufficiently uniform (or tailored) flow density map (distribution) throughout the heat transfer surface {712}. This provides sufficiently uniform cooling, and prevents significantly non-uniform temperatures.

A third feature is means to provide ample differential pressure compared to the minimum differential pressure for sufficient cooling. For one-phase flow, the incorporated reference describes that a modest pressure provides ample cooling. A mechanical pump can easily provide sufficient pressure.

For two-phase cooling at steady-state, the mass flow rate is relatively small, so the differential pressure is relatively small. This is provided by a thermo-siphon. This can provide a pressure related to the product of the following: the density difference between liquid and vapor; the altitude difference from the external condenser and heat exchanger {740} to the cold-plate {710}; the acceleration of gravity {260}.

Uniformity and maximum cooling: For a given heat density, cooling non-uniformity constrains the maximum total cooling capacity, and hence constrains maximum granularity. Pump-activated liquid flow enables easiest uniformity and largest granularity. Thermo-siphon activated flow generally provides intermediate uniformity and intermediate total cooling. Heat-pipe activated flow generally is most constrained by uniformity and total cooling.

Maintenance: Backup features are preferably exercised and verified frequently. For example, every day before sun-rise and just after sunset, there is maintenance that includes: blocking and opening the shutter; turning external power off and on; exercising tracking and other motions; verifying sufficient coolant; verifying all functions for both power-driven and power-independent cooling modes.

Preferably there is maintenance sufficiently often: to remove dust or other contamination from the optical subsystem, from the air fins, from high voltage insulation; to lubricate and verify movability of the mechanical and tracking subsystem; to replenish or replace coolant; to evaluate coolant chemistry; to remove contamination inside the cooling system, particularly from heat transfer surfaces.

Chemical engineering: For reliable operation, this cooling system depends on chemical engineering in its design, materials, manufacturing, and installation. This dependency is: least for single-phase pumped-liquid cooling; more for two-phase thermo-siphon cooling; most for two-phase heat-pipe cooling.

From prior arts of chemical engineering, pumped cooling, thermo-siphons, and heat pipes, the instant invention adopts known means to prevent or counteract: precipitation or deposition onto a heat transfer surface; electro-chemical effects, such as corrosion, etching, plating; leaching from polymeric hoses; evolution of gas that is dissolved in liquid coolant, or absorbed in a solid material, or emitted by a chemical reaction; leaky seals; permeable hoses; liquid or gas movement inward or outward.

In particular, to prevent electro-chemical effects, it is desirable to prevent water contact with a pair of metals that can product significant galvanic reaction. For example, it is preferable for water to contact only copper, stainless steel, ceramic dielectric or polymeric hose. By counter-example, it is unfavorable for water to contact both copper and iron.

The metal core is not copper, but the tubes are copper. It is desirable to have very thin copper coating on the inside wall of the PvMcm. This reinforces fluid sealing, and protects against galvanic reactions, particularly galvanic attack through slight cracks leading to a Mo core. This coating counterbalances the wiring on the outer surface of the substrate, and thus prevents bimetallic strip bending. Also, copper is relatively elastic and very thin. This further minimizes thermo-mechanical effects.

### Large-Scale View, FIG. {112}

This figure shows structures and relations which are too large to be visible in other figures. Since items very considerable in size, various parts of this figure have various scales. A wiggly spline indicates a change in scale. In the figure, elements are located for graphic clarity, which may not correspond to the actual geometry.

This system is preferably located in a clear climate, with bright ambient sunlight {910} through-out most hours of most days.

There is a primary solar concentrator {911}. Preferably this is a very large concave mirror {912} formed by a balloon-mirror {913}. This is aluminized on one hemisphere {914}, and transparent on the other hemisphere {915}.

The primary concentrator is held by an equatorial band {921} in a mechanical system {920} which can rotate the collector. There is a tracker {922} which accurately aims the concentrator at ambient sunlight. This tracker and related hardware serves as a type of shutter {923}.

There is a large secondary mirror {931}, mounted on a hinge {982}, moved by an actuator {933}. This includes an electromagnet {934}, a ferromagnetic rotor {935}, and a spring {936}. Together these serve as another type of shutter {937}.

From the primary collector, conical sunlight {938} is reflected by the secondary mirror to an enclosure {940} and solar power generation receiver {950}. Concentrated sunlight {941} enters through a window {942} with liquid cooling. Just inside is a mirror (or reflector) {943} which is thermo-conductive and very massive. This is mounted on an axle {944} with an actuator {945}. Thus the mirror can serves as another type of shutter {946}. From this mirror, heat conducts through the axle, to large air fins {947} located outside the enclosure. There is an insulated mechanical linkage {948} to move the shutter and to control the discrete switch (see below) {959}.

There are many PV cells {941} designed for high PV efficiency and intense illumination. These are mounted in a dense array {952} upon a PvMcm {953}. This has a specialized substrate which simultaneously provides many functions: heat transfer; DC electrical wiring; AC transmission-lines; HV insulation and safety.

There is a cold-plate {961} for liquid cooling with special structures to remove very intense heat flux and very large total heat power. There is a thermal path {962} with low ThRy, from each PV cell, through the PvScm, into the cold-plate, and into flowing cool liquid {963}. Also (see below) there is a thermal path from each switch {964}, through the substrate of the SwMcm {965}, into the cold-plate {966}, and into flowing cool liquid {967}.

From the PvMcm {953}, there is an electrical jumper {954}. This connects to a SwMcm {955} with solid-state switches {956} designed for high voltage and high current. From the SwMcm, there is a short cable {957} that connects to discrete capacitors {958} and to a discrete switch {959} for high voltage and high current. Short cables {961} go to power connectors {962} which penetrate the enclosure. Next are paired cables {963} that deliver AC power {964} possibly through a significant distance to a load {965} which directly consumes this power. Alternatively, the load may be a transformer {971 } which generates higher voltage AC {972}. This feeds through a distribution system {973} to a distant ultimate load {974}.

For the enclosure, the shutter, each cable, and the load or transformer, each has an independent and permanent ground connection {979}.

### Substrate Variations

Let “variations” be understood to mean additional embodiments.

Preferred embodiment: This has solid molybdenum for the core, sintered powder molybdenum for wiring, aluminum nitride for both the inner dielectric layers (on each face of the core) and the outer dielectric (on the outside of wiring). The dielectric may include various additives to facilitate sintering, and binders for fabrication. This provides excellent areal thermal resistivity, and excellent dielectric strength. The metal core provides mechanical strength, and thus prevents cracking of aluminum nitride, which is a brittle material. For large-scale production, the first fabrication family is HTCC-M, which is described in another section.

Ceramic variations: There is a vast prior art of ceramic and their fabrication, particularly including ceramic substrates for printed circuits. Many are suitable for this substrate.

A second fabrication family uses a high temperature process to deposit a thermo-conductive ceramic on both faces of the core. Representative processes include plasma deposition, chemical vapor deposition, or hot spray. One precedent is U.S. Pat. No. 4,777,060 by Mayr et al., titled “Method for making a composite substrate for electronic semiconductor parts”. In particular, this can deposit AlN on Mo.

A third fabrication family is “Low Temperature Co-fired Ceramic with Metal core” (LTCC-M). To the AlN power, this adds a glass-like binder. This enables sintering at a less hot temperature, typically below 1,000 C. The result is a composite: glassy ceramic filled with AlN. This reduces fabrication cost but also degrades some relevant properties. Its thermal conductivity is not as excellent as pure AlN. Nevertheless, this may be adequate for the SwMcm or a PvMcm for a system with less highly concentrated sunlight. This composite has a CTE larger than pure AlN. However this is mechanically constrained by the core, which has much greater in-plane stiffness. Therefore the overall substrate has CTE similar to the core. A precedent is U.S. Pat. No. 6,713,862, by Palansiamy et al, titled “Low Temperature co-fired ceramic-metal packaging technology”.

The fields of ceramic substrates and printed circuits for electronics provide many technologies suitable for embodiments of this invention. For an ordinary engineer who understands this invention and who works in these fields or follows this literature, these and many more embodiments will be readily apparent.

Variation with quadrants and prefabricated AlN: In some cases, the largest available AlN plate is smaller than the desired PvMcm. For example, these are sizes are respectively ˜30 cm and ˜60 cm. However Mo plates are available with size ˜60 cm or larger.

Therefore each dielectric layer consists of 4 quadrants, each one prefabricated plate. However the core spans the entire PvMcm. This provides a hydraulic seal and mechanical stiffness that span the entire PvMcm, including gaps between quadrants. As per FIG. {103}, each printed wire circuit is complete within one quadrant.

In another case, each dielectric layer is formed by 8 triangular plates, and each printed wire sector is within one plate. In still other cases, two adjacent plates have two printed wires that are connected through a short discrete wire. Thus a very large PvMcm can be made of considerably smaller prefabricated plates.

Core and stiffness: Aluminum nitride and many ceramics are brittle. A core which provides matching CTE and sufficiently stiffness thereby prevents straining and eventually cracking the ceramic. A simple version is a metal core plate with sufficient thickness. Bulk metal cost scales with thickness. This cost is economically counter-balanced by the high power density of this invention.

Core stiffness can be enhanced by other variations which add thickness. One example is ribs which protrude from the core. For example, the metal core is embossed to form ribs. Another core variation is a sandwich, with two metal layers separated by a middle layer of a thermo-conductive material. More generally, the middle layer can be dielectric or electro-conductive. The middle layer may be hard with matching CTE, or soft with almost any CTE. For the middle layer, one embodiment is AN, and another embodiment is copper. Yet another core embodiment is a sandwich with two outer copper layers, and middle molybdenum layer.

These and other versions can provide sufficient stiffness, even with thin metal layers and less metal cost, but with more fabrication effort. Also, versions with thin metal layers enable suitable cores with metal that has less excellent bulk thermal conductivity. Depending of the core embodiment and it fabrication, the maximum temperature may be as high at ˜1,800 C, or as moderate as ˜350 C.

These enable using metal various elements and alloys. Thus core metal embodiments include molybdenum, tungsten, nickel or many alloys, such as Fe—Ni alloys (Invar or Nilo) or Copper-Tungsten alloys. However metal prices vary considerably from year to year.

Other highly thermo-conductive ceramics: The art of ceramics is vast and growing, and provides a growing number of ceramics with high thermal conductivity. There is work to reduce costs and to develop even better ceramic materials. As these mature technologically and costs decrease, such ceramics provide a growing number of additional embodiments.

Today such ceramics include: boron nitride; silicon nitride, particularly beta silicon nitride; boron nitride with silicon nitride. This list will grow year by year. Additives are used to improve grain boundaries, to improve sintering, to provide binding during fabrication. Many of the fabrication processes described above are applicable for these ceramics.

Also, some ceramics enable special fabrication methods. For example, silicon nitride fabrication can start with a silicon plate. This is heated and exposed to nitrogen, and thus transforms into silicon nitride.

Non-metallic core: Technology is improving to fabricate large plates of various covalent solids. Some have relatively good thermal conductivity, and provide a variation for the core. Since this plate is solid, it thermal conductivity is better than a sintered ceramic with the same composition. Today one example is synthetic sapphire (Al203). Its CTE is 7.8E-6 per K. Today this is uses in windows for supermarket scanners, and its price is surprising low. Thus the core is both also a dielectric that has a high product for its thermal conductivity multiplied by it dielectric strength.

Polymeric dielectric filled with thermo-conductive dielectric material: The following variation offers some advantage of thermo-conductive dielectric with some advantages of polyimide plastic.

Some polymers provide especially good electrical dielectric strength, although relatively poor bulk thermal conductivity. An example is polyimide, such as Dupont “KaptonCR”. This is semi-crystallized, so its thermal conductivity is slightly less poor. Representative parameters are roughly 200E6 V/M for electrical dielectric strength, and thermal conductivity may be about 0.3 W per (M*K). This is designed for excellent durability against electrical corona discharge, and might also have durability against sunlight.

Bulk thermal conductivity is improved by “filling” the polymer with fine grains of a dielectric material. Such composite materials are available commercially, but with a. These are used as a thermal interface. For example DuPont makes “KaptonMT”. This is a semi-crystalline polyimide filled with alumina powder. Also, silicone tape filled with boron nitride has been used as an experimental dielectric for capacitors embedded in printed circuits.

Instead of this, a better tape or coating should be semi-crystalline polyimide filled with grains of a dielectric material with high thermal conductivity and high dielectric strength. Two examples are aluminum nitride and boron nitride. Also, the polymer should include an additive to provide provides UV absorption. For this combination, its dielectric strength will exceed 100E6 V per M, and its thermal conductivity will be roughly 1.0 W per (M*K). Thus a layer with thickness 25 M will provide breakdown voltage BV=2.5 kV, and ThRy=25E-6 K per (W/M̂2). At heat flux 60 W/cm̂2=0.6E6 W/M̂2, three dielectric layers will cause a temperature drop of 75 C.

Another variation has a thicker dielectric between printed wiring and the core, less thick dielectric outside of the printed wiring, and least thick dielectric on the surface inside the cold-plate. This would provide adequate insulation with smaller total ThRy. As a dielectric for a variation of this invention, this coating potentially offers: lower cost; sufficient electrical insulation; significantly small ThRy. Its durability may be sufficient to be useful, although less than an all-ceramic dielectric. This dielectric may be useful for an embodiment with less highly concentrated sunlight. Here its moderate substrate cost per area balances the moderate electrical output power per area.

A substrate variation starts with a core with suitable CTE. For example, this is a relatively thick Mo plate, such as 0.5 to 1.0 mm thick. Another core is a laminate, such as (Mo/Cu/Mo) or (Cu/Mo/Cu). Another core is a sandwich, such as of (Mo/AlN/Mo).

On each outer surface of the core, a layer of this coating is applied and cured to form as a dielectric. On one face, metal wire is applied, followed by outer dielectric layer, followed by bonding pads. For these fabrication steps, suitable technology is provided by the prior art of printed circuit boards. The CTE of this overall substrate is close to the core, and approximately matches the CTE of the PV cells. The core has in-plane stiffness that is vastly larger than the dielectric including the polymer. Thus the core dominates the CTE of the substrate. During thermal cycles, the soft polymer is slightly stretched or compressed by the core. The polymer is sufficiently elastic and sufficiently tolerant of fatigue that it can tolerate many such thermal cycles without cracking.

This substrate is novel over the prior art because this uses dielectric material (AlN or BN) which has high thermal conductivity and high dielectric strength, together with Mo core which provides a CTE that matches PV cells. Also, this combination coating provides a high product of thermal conductivity multiplied by dielectric strength, even though its thermal conductivity is far smaller than AlN.

SwMcm variations: The PvMcm must cool a very intense heat flux, and a suitable substrate is described above. The SwMcm has much smaller small flux, concentrated at a few locations. This enables easier options for the substrate for the SwMcm.

One embodiment uses the same substrate technology (pure AlN over Mo using HTTC-M fabrication) for both the PvMcm and SwMcm. This may be preferable in very high production, where the incremental cost of additional is relatively small.

Another embodiment takes advantage of these differences. The PvMcm is pure AlN over Mo, fabricated by the HTC-M process. This provides outstanding thermal properties, and excellent high voltage insulation, but appreciable cost. The SwMcm is uses a less expensive substrate technology. One suitable variation is glass ceramic with AlN filling, over a Mo core. Another suitable variation is a polymer filled with a thermo-conductive ceramic, over a Mo core.

PV cell material variations: The preferred embodiment uses a PV cell which has high efficiency and supports high current density. Today this starts with a germanium wafer and adds three PV junctions.

Nevertheless, there is intense development of silicon PV cells. Perhaps this eventually will lead to a silicon-based PV cell with high efficiency and support for high current density. If so, that too would enable an embodiment of this invention.

Also, there is intense development of deposited PV cells, including some deposited upon a dielectric wafer. This is sometimes called “Semiconductor on Insulator”. This insulator might be a thermo-conductive ceramic substrate, particularly the third family described above. It is remotely possible that eventually someone might develop such a PV cell that provides high efficiency and support high current density. If that occurs, it would lead to additional embodiments of this invention.

In the claims which follow, let “a substrate including means to attach PV cells” be understood to also include a substrate with deposited PV cells, as well as embodiments where a discrete PV cell or PvScm is attached to pads upon the substrate.

Such variants might be more probable (or less improbable) as embodiments for PV cells with less high efficiency, excited by less highly concentrated sunlight.

Further substrate variations: Another substrate variation with a mechanical reinforcement external to the substrate. This reinforcement has CTE which matches the PV cells. This reinforcement is to be considered as another type of core.

Another variation is a solar receiver with wider PV chips on a wider PvMcm etc, as per the teaching of this invention.

For Ge, Mo and AN, the CTE match is very close. This enables another variation. This generally follows all the above descriptions, but has wider PV cells on a wider PvMcm and solar receiver. For example, the PV cells are (22 mm)̂2.

### Cooling Variations

Other cooling fluids: The preferred coolant is water, preferably but optionally with additives such as anti-freeze, corrosion inhibitors, anti-algae compounds.

Water has excellent heat capacity and good thermal conductivity (compared to other liquids). Therefore single-phase cooling with impingement very efficiently removes heat from a smooth surface. This is the preferred embodiment.

Other cooling fluid embodiments include various hydrocarbon fluids, silicone fluids or refrigerant fluids, such as R245FA. Other embodiments include organic or synthetic heat transfer fluids. These and other fluids are commercially available for heat transfer. However these fluids have significantly less heat capacity and thermal conductivity, and thus are less suitable for impingement single-phase cooling on a smooth surface. Instead, these are more suitable for cooling with small fins and grooves.

Small fins and grooves: Another embodiment provides fins and grooves on the heat transfer surface. It is optimal that the ratio of fin height divided by fin width is be comparable to the square root of the ratio of fin bulk thermal conductivity divided by the bulk thermal conductivity of the coolant fluid. It is optimal that the groove width is comparable to the fin width. The overall heat transfer coefficient improves reciprocally with the pitch of the fins and grooves. Thus narrower fins and grooves provide better heat transfer. An internal manifold provides highly parallel flow into and out of these fins and grooves. This greatly facilitates provides providing ample flow with low pressure, in spite of narrow fins and grooves and a viscous fluid. This embodiment should follow the teaching of U.S. Pat. No. 5,388,635, and that is included by reference. That provides descriptions and figures, including the internal manifold structure and related hydrodynamics to provide ample flow in spite of low pressure.

Two-phase cooling with pumping: This variation normally uses two-phase cooling (possibly with a thermo-siphon pumping) simultaneously with two pumps, each driven by external power. This provides extra pressure, and thus provides especially intense two-phase cooling. Such cooling is well known in the prior art of liquid cooling, where it is called “flow-boiling” or “force-fed boiling”. One reference is cited above, in the section on Prior Art.

This is two-phase cooling and that takes advantage of the heat of vaporization. Therefore a relatively small mass flow rate is sufficient. A somewhat larger flow further enhances flow boiling. Even so, each pump is driven by relatively little power.

Again, the preferred coolant is water. This has an especially large heat of vaporization. Thus each pump consumes especially small power. Each pump is backed up by a relatively small battery. When external power fails, then this battery provides sufficient power and sufficient energy for transitional cooling.

Heat pipe cooling mode and embodiment: A capillary wick {727} leads to the inner surface {712} of the outer wall {711} of the cold-plate {710}. For example, this wick includes thermo-conductive small metal grains sintered to each other and to the inner surface. This enhances heat transfer as follows. By capillary action, this wick draws supply liquid {241} to this inner surface {712}. Also this enables evaporation with very little thermal overshoot. Thus supply liquid {241} absorbs heat and becomes return vapor {244} and expands greatly.

A heat pipe can provide two-phase circulation and cooling independent of height differences or external power. A heat pipe effectively provides small differential pressure. Therefore cooling uniformity may constraint the maximum feasible size of the cold-plate, PvMcm and overall power. Also a heat pipe is especially vulnerable to non-condensable gases and various chemical effects. This may be a reliability challenge, or require a most expensive engineering. One example includes metal tubes and hermetic sealing of the coolant region.

Heat pipe: For two-phase cooling, this activates fluid circulation by evaporation of a liquid and condensation of vapor. From the evaporator to condenser, this provides a wick with fine pores. Thus capillary action draws liquid from the condenser back to the evaporator. This provides another mode for two-phase cooling. A loop heat pipe has separate tubes for flow of supply liquid and return vapor. This provides some advantages, compared to both flows in the same tube.

A heat pipe cooling mode can be superimposed on the cooling system in FIG. {109}. Thus the cold-plate {710} is the evaporator and the external heat exchanger {740} is the condenser.

For closed-loop cooling with long-term reliability, a heat requires especially good chemical engineering. However, as the total heat power increases (thus larger granularity) it more challenging for a heat pipe to operate with sufficient uniformity across the evaporator.

Even so, capillary action can useful to augment two-phase cooling using a thermo-siphon. Also, capillary action can augment providing coolant to the cold-plate during open-loop two-phase cooling. For example, a wick-like structure is included on heat-transfer surface, the nozzle sheet, and the supply conduits. One example uses the small gap between nozzle sheet and heat transfer surface, or applies a texture to the surfaces. Another example adds a porous coating inside the supply conduit and supply tube.

1. A substrate for holding an array of photovoltaic power cells, comprising:
a core having a low coefficient of thermal expansion;
a dielectric material having a high product of its bulk thermal conductivity multiplied by its dielectric strength; and
power wires on the substrate for electrically connecting a plurality of the photovoltaic power cells.

2. The substrate of claim 1 wherein the core is metal.

3. The substrate of claim 1 wherein the core further comprises molybdenum, tungsten, or nickel.

4. The substrate of claim 1 wherein the dielectric material further comprises a ceramic material.

5. The substrate of claim 1 wherein the dielectric material further comprises aluminum nitride.

6. The substrate of claim 1 wherein the dielectric material is embedded in a polymer material.

7. The substrate of claim 1 wherein the core has a coefficient of thermal expansion about equal to the coefficient of thermal expansion of the photovoltaic power cell.

8. The substrate of claim 1 wherein the core has a coefficient of thermal expansion in the range of about 2 E-6 per K to about 6 E-6 per K.

9. The substrate of claim 1 wherein the core has a coefficient of thermal expansion that differs from the photovoltaic cell's coefficient of thermal expansion by less than 5 E-6 per K.

10. The substrate of claim 1 wherein the core has a coefficient of thermal expansion that differs from the photovoltaic cell's coefficient of thermal expansion by less than 2.5 E-6 per K.

11. The substrate of claim 1 wherein the dielectric material has a thermal conductivity greater than about 60 W per (M*K).

12. The substrate of claim 1 wherein the dielectric material has a thermal conductivity greater than about 120 W per (M*K).

13. The substrate of claim 1 wherein the dielectric material has a dielectric strength greater than about 6E6 V per M.

14. The substrate of claim 1 wherein the dielectric material has a dielectric strength greater than about 14E6 V per M.

15. The substrate of claim 1, wherein the dielectric material has a product of its thermal conductivity and its dielectric strength which is greater than about 3.5E7 (V*W) per (K*M̂2).

16. The substrate of claim 1, wherein the dielectric material has a product of its thermal conductivity and its dielectric strength which is greater than about 3.5E8 (V*W) per (K*M̂2).

17. The substrate of claim 1, further comprising a cold-plate that is arranged to thermally transfer heat to a flowing liquid.

18. The substrate of claim 17, wherein the cold-plate has a heat transfer surface, the cold-plate being constructed to allow fluid flow to and from substantially all the heat transfer surface, resulting in fluid in-flow and fluid out-flow which are substantially topologically parallel between separated locations on this surface.

19. The substrate of claim 1, further comprising a ground plate, wherein the power wires and ground plate are constructed so that a corresponding photovoltaic power generation circuit has significant distributed capacitance.

20. The substrate according to claim 19, further comprising a photovoltaic power generation circuit that approximates a transmission line that has a characteristic impedance, and has a DC source impedance, and are structured to provide a characteristic impedance that is lower than the DC source impedance.

21. The substrate according to claim 1, further comprising a photovoltaic power generation circuit that is electrically isolated from said metal core.

22. The substrate according to claim 21, wherein a dielectric layer provides the electrical isolation.

23. A solar power generation module holding an array of photovoltaic power cells, comprising:
a substrate, further comprising:
a metal core having a low coefficient of thermal expansion;
a dielectric layer having high bulk thermal conductivity and a high dielectric strength; and
power wires on the substrate for electrically connecting a plurality of the photovoltaic power cells;
a plurality of photovoltaic power cells mounted and arranged in an array on the substrate;
a cold plate in thermal communication with the photovoltaic cells; and
wherein the cold plate has fluid paths which provide topologically highly-parallel fluid flow to remove heat from the substrate.

24. The solar power generation receiver of claim 23, wherein the cold-plate and the fluid cooling structure is arranged so that when the power cell array is being subjected to concentrated solar energy, the temperature across the array and within each photovoltaic cell is substantially within an operational range for the photovoltaic process.

25. The solar power generation receiver of claim 23, wherein the cold plate, substrate, and the fluid cooling structure are made so that the local thermal resistivity is sufficiently low substantially throughout the face of substantially all the photovoltaic cells.

26. The solar power generation receiver of claim 23, wherein the cold-plate and the liquid cooling structure further comprise a heat transfer surface, and the module further comprises a plurality of nozzles arranged for squirting fluid jets on the heat transfer surface.

27. The solar power generation receiver of claim 26, wherein the heat transfer surface further comprises a plurality of thermally conductive fins or grooves arranged.

28. A solar power generation receiver holding an array of photovoltaic power cells, comprising:
a substrate, further comprising:
a metal core having a low coefficient of thermal expansion;
a dielectric layer having high bulk thermal conductivity and a high dielectric strength; and
power wires on the substrate for electrically connecting a plurality of the photovoltaic power cells.
a plurality of photovoltaic power cells mounted in an array on the substrate;
an inverter switch connected to the substrate; and
a cooling structure common to both the substrate and the inverter switch.

29. The solar power generation receiver according to claim 28, wherein the cooling structure further comprises:
a cold-plate in thermal communication with the photovoltaic cells; and
wherein the cold-plate has a pathway for a liquid to remove heat from the substrate and the inverter switch.

30. The solar power generation receiver according to claim 29, wherein the substrate, inverter, and cold-plate are connected and positioned adjacent to each other.

31. A solar power generation system comprising:
a photovoltaic power generator delivering power on two or more power output lines;
a protective enclosure;
at least one grounded connection connected to the protective enclosure and also connected to the power generator; and
wherein the voltage between two of the power lines exceeds the voltage between each power output line and ground.

32. The solar power generation system according to claim 31, wherein the generation system has a defined safety reference voltage, and wherein the absolute value of voltage from any power output to ground does not exceed the reference safety voltage, but the voltage difference between power outputs exceeds the reference safety voltage.

33. A photovoltaic power generation system, comprising:
photovoltaic power cells positioned in a light path from a solar concentrator;
a cooling system for removing excess heat from the photovoltaic cells;
a sensor which generates a signal correlated with cooling system failure;
an optical element that can change the light path; and
wherein the optical element is responsive to the signal.

34. The photovoltaic power generation system according to claim 33, wherein the optical element comprises a shutter in the form of a tracker, a mirror, a reflector, a refractor, a lens, a prism, a scatterer, or an absorber.

35. The photovoltaic power generation system according to claim 33, wherein the optical element is a moveable.
